(19) United States
(12) Patent Application Publication
(10) Pub. No.: US 2021/0370259 A1
(43) Pub. Date: Dec. 2, 2021

(54) GAS SUPPLY PACKAGES, ADSORBENTS, AND RELATED METHODS

(71) Applicant: ENTEGRIS, INC., Billerica, MA (US)

(72) Inventors: Lawrence H. Dubois, Danbury, CT (US); Donald J. Carruthers, Reno, NV (US); Melissa A. Petruska, Newton, CT (US); Edward A. Sturm, New Milford, CT (US); Shaun M. Wilson, Trumbull, CT (US); Steven M. Lurcott, Deerfield, FL (US); Bryan C. Hendrix, Danbury, CT (US); Joseph D. Sweeney, New Milford, CT (US); Michael J. Wodjenski, New Milford, CT (US); Oleg Byl, Southbury, CT (US); Ying Tang, Brookfield, CT (US); Joseph R. Despres, Middletown, CT (US); Matthew Thomas Marlow, Austin, TX (US); Christopher Scannell, Middlebury, CT (US); Daniel Elzer, Gilbert, AZ (US); Kavita Murthi, Fremont, CA (US)

(21) Appl. No.: 17/398,891

(22) Filed: Aug. 10, 2021

Related U.S. Application Data
(63) Continuation of application No. 15/773,652, filed on May 4, 2018.
(60) Provisional application No. 62/252,437, filed on Nov. 7, 2015.

(51) Int. Cl. B01J 20/10; B01J 20/20; B01J 20/22; B01J 20/28; F17C 11/00; H01L 21/67; B01J 20/26; B01J 20/02

(52) U.S. Cl. CPC B01J 20/103; B01J 20/20; B01J 20/226; B01J 20/28016; B01J 20/2803; B01J 2203/00; B01J 20/2808; F17C 11/00; H01L 21/67017; B01J 20/261; B01J 20/0211; B01J 20/28042

(57) ABSTRACT

Adsorbents of varying types and forms are described, as usefully employed in gas supply packages that include a gas storage and dispensing vessel holding such adsorbent for storage of sorbate gas thereon, and a gas dispensing assembly secured to the vessel for discharging the sorbate gas from the gas supply package under dispensing conditions thereof. Corresponding gas supply packages are likewise described, and various methods of processing the adsorbent, and manufacturing the gas supply packages.

### RELATED APPLICATIONS

This application is a continuation of U.S. application Ser. No. 15/773,652, filed on May 4, 2018 and entitled “ADSORBENTS AND FLUID SUPPLY PACKAGES AND APPARATUS COMPRISING SAME,” which is a National Stage Entry of PCT/US2016/060520, filed on Nov. 4, 2016 and entitled “ADSORBENTS AND FLUID SUPPLY PACKAGES AND APPARATUS COMPRISING SAME,” which claims the benefit of and priority to U.S. Provisional Application Ser. No. 62/252,437, filed on Nov. 7, 2015, all of which are incorporated herein by reference in their entireties for all purposes.

### FIELD

The present disclosure relates to adsorbents useful as a reversible storage medium for fluids, on which fluids may be adsorbed for storage, and from which adsorbed fluid may be desorbed for subsequent use or disposition. The disclosure further relates to fluid supply packages comprising adsorbent as a fluid storage medium, and to apparatus comprising same.

### DESCRIPTION OF THE RELATED ART

Adsorbent-based fluid supply packages have been widely commercialized in semiconductor manufacturing and other industries, in which fluid is reversibly adsorbed on a solid-phase physical adsorbent for storage thereon, and is desorbed from the adsorbent under fluid dispensing conditions to provide the fluid for use. Examples of such fluid supply packages include those commercially available from Entegris, Inc. (Billerica, Mass., USA) under the trademarks SDS, PDS, Pure Delivery System, and SAGE.

Adsorbents of various types have been employed in such fluid supply packages. Carbon adsorbents are widely utilized, and can be formed with varied porosity, pore size, pore size distribution, sorptive affinity, fluid specificity, bulk density, particle or piece size, shape, and other characteristics, rendering them highly advantageous for use in fluid supply packages.

The art is engaged in a continuing effort to develop adsorbents for use in fluid supply packages, as well as to develop fluid supply packages in which such adsorbents are used as a medium for adsorptive retention of fluid under fluid storage conditions and for desorptive release of fluid under fluid dispensing conditions.

### SUMMARY

The present disclosure relates to adsorbents that are useful as reversible fluid storage and dispensing media, as well as to fluid supply packages and apparatus comprising same, and to methods of making and using such adsorbents, fluid supply packages, and apparatus.

In one aspect, the disclosure relates to a composition for supplying fluid for use, comprising adsorbent having fluid reversibly adsorbed thereon, wherein the adsorbent comprises material selected from the group consisting of titania, zirconia, silicalite, metal organic framework (MOF) materials and polymer framework (PF) materials, wherein the fluid comprises fluid for manufacturing semiconductor products, flat-panel displays, solar panels, or components or subassemblies thereof, and wherein when the fluid comprises silane or disilane, the adsorbent may additionally comprise silica. In a specific aspect, the fluid comprises fluid selected from the group consisting of silane, disilane, germane, diborane, and acetylene.

Another aspect of the disclosure relates to a composition for supplying silane for use, comprising silica or silicalite having silane reversibly adsorbed thereon.

A further aspect of the disclosure relates to a fluid supply package, comprising a fluid storage and dispensing vessel containing a composition as described above, and a dispensing assembly configured to dispense fluid from the vessel under dispensing conditions.

In another aspect, the disclosure relates to a method of supplying fluid for use, comprising subjecting a composition, as described above, to dispensing conditions.

Yet another aspect of the disclosure relates to a method of supplying fluid for use, comprising dispensing fluid under dispensing conditions from a fluid supply package as described above.

A further aspect of the disclosure relates to a method of manufacturing a product selected from the group consisting of semiconductor products, flat-panel displays, solar panels, and components and subassemblies thereof, such method comprising use of fluid desorbed from a composition as described above, in a manufacturing operation of such method.

Another aspect of the disclosure relates to a method of manufacturing a product selected from the group consisting of semiconductor products, flat-panel displays, solar panels, and components and subassemblies thereof, such method comprising use of fluid dispensed from a fluid supply package as described above, in a manufacturing operation of such method.

In one aspect, the disclosure relates to a method of producing reduced size particles of nanoporous carbon from a nanoporous carbon starting material, the method comprising: introducing an infiltrating agent into porosity of the nanoporous carbon starting material; and activating the infiltrating agent to exert exfoliatingly effective expansive action on the porosity of the nanoporous carbon starting material, to exfoliate the nanoporous carbon starting material and produce nanoporous carbon particles of reduced size from the nanoporous carbon starting material.

In another aspect, the disclosure relates to nanoporous exfoliate carbon particles, such as may be produced by the above type described method.

In a further aspect, the disclosure relates to a method of forming a multi-layer assembly structure that is pyrolyzable to form a carbon pyrolyzate adsorbent, such method comprising forming a multi-layer structure comprising at least one layer of a pyrolyzable starting material and at least one layer of an evanescent material, and processing the multi-layer structure to form a multiplicated multi-layer structure including an increased number of layers of pyrolyzable starting material and evanescent material in relation to the multi-layer structure prior to such processing, as the multi-layer assembly structure that is pyrolyzable to form the carbon pyrolyzate adsorbent.

Another aspect of the disclosure relates to a method of forming a carbon pyrolysis adsorbate, comprising subjecting a multi-layer assembly structure produced by the method described above, to pyrolysis, to evanesce the evanescent material while pyrolyzing the pyrolyzable starting material in the pyrolyzable starting material layers in the multi-layer assembly structure, to yield the carbon pyrolyzate adsorbent.

Yet another aspect of the disclosure relates to a carbon pyrolyzate adsorbent produced by the method described above.

In another aspect, the disclosure relates to a method of making a carbon pyrolyzate adsorbent, comprising blending a pyrolyzable starting material with metal filaments to form a composite pyrolyzable starting material, pyrolyzing the pyrolyzable starting material to form a composite pyrolyzate, and contacting the composite pyrolyzate with a removal agent that is effective to at least partially remove the metal filaments from the composite pyrolyzate, to form the carbon pyrolyzate adsorbent.

A further aspect of the disclosure relates to a carbon pyrolyzate adsorbent, which is manufactured using a process as described in the preceding paragraph.

Another aspect of the disclosure relates to a process for fabricating a gas supply package, comprising pyrolyzing a pyrolyzable starting material in a pyrolysis furnace to form a carbon pyrolyzate adsorbent that is discharged from the pyrolysis furnace at a discharge locus, and packaging the carbon pyrolyzate adsorbent at the discharge locus in a gas storage and dispensing vessel including a dispensing assembly, to form the gas supply package.

A further aspect of the disclosure relates to a pre-package of carbon pyrolyzate articles, comprising a container holding an array of carbon pyrolyzate articles, the container being gas-impermeable and configured to be subsequently opened in situ after the prepackage of carbon pyrolyzate articles has been installed in a gas supply package.

The disclosure in another aspect relates to a gas supply package comprising a gas storage and dispensing vessel holding a pre-package of carbon pyrolyzate articles as described above, and a gas dispensing assembly secured to the gas storage and dispensing vessel.

In a further aspect, the disclosure relates to a method of supplying gas for use, comprising providing for installation in a gas supply package a pre-package of carbon pyrolyzate articles as described above.

A further aspect of the disclosure relates to a method of supplying a gas for use, comprising installing in a gas supply package a pre-package of carbon pyrolyzate articles as described above.

Yet another aspect of the disclosure relates to a method of supplying a gas for use, comprising opening a pre-package of carbon pyrolyzate articles as described above, in situ in a gas supply package.

A further aspect of the disclosure relates to a method of enhancing purity of a carbon pyrolyzate adsorbent, comprising contacting the adsorbent with a displacing gas that is effective to displace impurities from the adsorbent, and removing the displacing gas from the adsorbent, to yield an enhanced purity carbon pyrolyzate adsorbent.

In another aspect, the disclosure relates to a gas supply package comprising adsorbent for holding adsorbed gas for storage thereon and desorbing gas for discharge from the gas supply package under dispensing conditions of the package, wherein the adsorbent comprises molybdenum disulfide (MoS₂).

A further aspect of the disclosure relates to a method of enhancing purity of a carbon pyrolyzate adsorbent, comprising providing the adsorbent in a divided form and divided form size to achieve removal of at least 98% by weight of impurities in the carbon pyrolyzate adsorbent when the adsorbent is subjected to degassing, and degassing the adsorbent to achieve said removal.

Yet another aspect of the disclosure relates to a gas supply package comprising a gas storage and dispensing vessel holding an adsorbent gas storage medium, and a gas dispensing assembly secured to the vessel, wherein the vessel comprises a material of construction having a relatively higher content of impurity susceptible to egress in an interior volume of the vessel and presenting an interior surface in the interior volume of the vessel, wherein the interior surface is plated with a material having a relatively lower content of impurity susceptible to egress in the interior volume of the vessel.

In another aspect, the disclosure relates to a gas supply package comprising a gas storage and dispensing vessel holding an adsorbent gas storage medium, and a gas dispensing assembly secured to the vessel, wherein the vessel comprises aluminum or aluminum alloy as a material of construction.

The disclosure relates further to a method of enhancing purity of gas dispensed from a gas supply package comprising a gas storage and dispensing vessel holding an adsorbent gas storage medium, and a gas dispensing assembly secured to the vessel, such method comprising fabricating the vessel of the gas supply package to comprise interior vessel surface having a polished, smooth interior surface finish.

Another aspect the disclosure relates to a method of enhancing purity of gas dispensed from a gas supply package in use, the gas supply package comprising a gas storage and dispensing vessel holding an adsorbent gas storage medium, and a gas dispensing assembly secured to the vessel, wherein the vessel comprises interior volume including a headspace above the adsorbent gas storage medium, the method comprising quick-pumping the headspace, before or after charging the package with sorbate gas.

The disclosure in another aspect relates to a gas supply package kit, comprising (i) a gas supply package comprising a gas storage and dispensing vessel holding an adsorbent gas storage medium having sorbate gas adsorbed thereon, and a gas dispensing assembly secured to the vessel for discharging the sorbate gas from the package under dispensing conditions thereof, and (ii) post-fill analysis data for the supplied gas including gas purity, in a data presentation article or device.

The present disclosure in a further aspect relates to a gas supply package comprising a gas storage and dispensing vessel holding an adsorbent gas storage medium for storage of sorbate gas thereon, and a gas dispensing assembly secured to the vessel for discharging the sorbate gas from the package under dispensing conditions thereof, wherein the vessel comprises a DOT3AA cylinder, and the adsorbent gas storage medium comprises a PVDC-based polymer or copolymer pyrolyzate adsorbent, e.g., a PVDC-MA carbon pyrolyzate adsorbent. The adsorbent in such package may be in a pellet and/or bead form.

Another aspect of the present disclosure relates to a carbon pyrolyzate adsorbent article of rod form, having a length (L) to diameter (D) ratio in a range of from 20 to 90.

A further aspect of the disclosure relates to a bundle of such carbon pyrolyzate adsorbent articles of rod form.

A still further aspect of the disclosure relates to a gas supply package comprising a gas storage and dispensing vessel holding an adsorbent gas storage medium for storage of sorbate gas thereon, and a gas dispensing assembly secured to the vessel for discharging the sorbate gas from the package under dispensing conditions thereof, wherein the adsorbent medium comprises a bundle of carbon pyrolyzate adsorbent articles, wherein the bundle is positioned in a neck portion of the vessel and comprises carbon pyrolyzate adsorbent articles of rod form, having a length (L) to diameter (D) ratio in a range of from 20 to 90.

In one aspect, the disclosure relates to a method of manufacturing gas supply packages including packages used to supply different gases, wherein the gas supply packages each comprise a gas storage and dispensing vessel holding an adsorbent for storage of sorbate gas thereon, and a gas dispensing assembly secured to the vessel for discharging the sorbate gas from the package under dispensing conditions thereof, said method comprising preparing adsorbents by processing including pyrolysis of a pyrolyzable starting material and subsequent activation and degassing, followed by packaging of the adsorbents in the gas supply packages, wherein the processing is carried out according to processing conditions that are specific for the sorbate gas to be employed in a gas supply package comprising such adsorbent, and wherein the processing conditions differ for the adsorbents that are packaged in different gas supply packages for supply of different gases.

Another aspect of the disclosure relates to a method of reducing heels content at exhaustion of a gas supply package comprising a gas storage and dispensing vessel holding adsorbent for storage of sorbate gas thereon, and a gas dispensing assembly secured to the vessel for discharging the sorbate gas from the package under dispensing conditions thereof, such method comprising providing, as said adsorbent, adsorbent species of at least one of differing type and differing form, wherein the different type(s) and/or form(s) increase the amount of sorbate gas desorbed from the adsorbent under the dispensing conditions, in relation to adsorbent of a single one of such adsorbent species.

A still further aspect of the disclosure relates to a method of reducing heels content at exhaustion of a gas supply package comprising a gas storage and dispensing vessel holding adsorbent for storage of isotopically-enriched sorbate gas thereon, and a gas dispensing assembly secured to the vessel for discharging the sorbate gas from the package under dispensing conditions thereof, such method comprising initially charging the adsorbent in the gas storage and dispensing vessel of the gas supply package with corresponding non-isotopically-enriched sorbate gas in an amount sufficient to establish a gas heel, and after establishment of the gas heel, charging the adsorbent in the gas storage and dispensing vessel with the isotopically-enriched sorbate gas to a predetermined fill capacity of the gas supply package.

In another aspect, the disclosure relates to a gas supply package comprising a gas storage and dispensing vessel holding adsorbent for storage of sorbate gas thereon, and a gas dispensing assembly secured to the vessel for discharging the sorbate gas from the package under dispensing conditions thereof, wherein the sorbate gas inventory in the gas storage and dispensing vessel comprises a heel portion comprising non-isotopically-enriched sorbate gas, and a non-heel portion comprising corresponding isotopically-enriched sorbate gas.

Other aspects, features and embodiments of the disclosure will be more fully apparent from the ensuing description and appended claims.

### BRIEF DESCRIPTION OF THE DRAWINGS

FIG. 1 is a perspective view of a fluid supply package of the present disclosure, according to one embodiment thereof.

FIG. 2 shows a process sequence, in which a multi-layer structure is converted to a multi-layer assembly structure by successive folding steps.

FIG. 3 is a schematic representation of a sequential spreading, cutting, and stacking process that is utilized to convert a starting multi-layer structure to a multi-layer assembly structure.

FIG. 4 is a schematic perspective view of a roll comprising a multi-layered, multi-component wound material comprising an evanescent material and a pyrolyzable material.

FIG. 5 is a perspective view of a block, formed from a multi-layered sheet comprising layers of evanescent material and layers of pyrolyzable material.

FIG. 6 is a perspective schematic view of the block shown in FIG. 5, showing a variety of shapes cut therefrom for the production of discrete pieces of multi-layer material.

FIG. 7 is a perspective schematic view of a pyrolyzate gas-contacting article formed from a precursor article comprising layers of evanescent material and layers of pyrolyzable material.

FIG. 8 is a perspective schematic view of a gas-contacting carbon pyrolyzate article of a type that has been formed by layering of sheets of pyrolyzable material and sheets of evanescent material, followed by punching, cutting, or other forming operations, to yield a cylindrical article in which the adjacent sheets are parallel to one another, extending longitudinally in the cylindrical article, so that subsequent pyrolysis removes the evanescent material in the alternating sheets thereof, to yield flow passages of generally rectangular cross-section, transverse to the longitudinal axis of the carbon pyrolyzate article.

FIG. 9 is a perspective schematic view of a gas-contacting carbon pyrolyzate article formed of alternating layering of sheets of pyrolyzable material and sheets of evanescent material, in the manner of the carbon pyrolyzate article of FIG. 8, but having a square cross-section, rather than the circular cross-section in the article of FIG. 8.

FIG. 10 is a schematic elevation view rendering of a process system comprising feed rolls of pyrolyzable material and evanescent material, wherein the feed rolls are driven in the direction indicated by the associated arrows so that respective sheets of pyrolyzable material and evanescent material are received on the take-up roll, to provide a jelly roll confirmation precursor article that may be subjected to pyrolysis to form the carbon pyrolyzate article of the type shown in FIG. 7.

FIG. 11 is a simplified schematic perspective view of the process system of FIG. 10, showing the respective rolls thereof.

FIG. 12 is a simplified schematic perspective view of a similar process system to that shown in FIG. 11, but wherein top roll is a feed roll of screen, and bottom roll is a feed roll of pyrolyzable material, so that the jelly roll conformation of the resulting wound precursor article is made up of alternating layers of screen and pyrolyzable material.

FIG. 13 is a simplified schematic perspective view of another process system, in which a feed roll of pyrolyzable material provides a sheet of such pyrolyzable material that is taken up on the pyrolyzable article roll, and wherein the sheet of pyrolyzable material intermediate the feed and take-up rolls receives a coating of evanescent material from coating material dispenser.

FIG. 14 shows a block laminate that is pyrolyzable to form a product carbon pyrolyzate article having passages therein deriving from evanescent material that has been removed in the pyrolysis operation.

FIG. 15 is a perspective view of a multi-layer pyrolyzable article comprising three different types of layers.

FIG. 16 is a perspective view of the multi-layer pyrolyzable article of FIG. 15, from which may be cut a multiplicity of shaped pieces.

FIG. 17 is a perspective schematic view of a carbon pyrolyzate fluid-contacting article according to another embodiment of the disclosure, as manufactured from a jelly roll conformation precursor article including cylindrically wound layers of evanescent material-impregnated screen alternating with layers of pyrolyzable material, with the precursor article having been subjected to pyrolysis conditions to form fluid passages between the carbon pyrolyzate laminae in which the screen, formed of a material unaffected by the pyrolysis operation, serves as a spacer between the carbon pyrolyzate layers.

FIG. 18 is a schematic representation of a fabrication facility for manufacturing a gas supply package according to one aspect of the disclosure.

FIG. 19 is a schematic representation of a processing sequence for introducing high-purity carbon pyrolyzate adsorbent to a gas supply vessel that then is completed with a valve head assembly being installed, subsequent to which the adsorbent is exposed in situ.

FIG. 20 is a schematic representation of a gas supply package according to a further aspect of the disclosure, comprising adsorbent in a multiplicity of forms, including rods that are bundled in the neck of the gas storage and dispensing vessel of such package.

### DETAILED DESCRIPTION

The present disclosure relates to adsorbents that are useful as a reversible fluid storage and dispensing media, as well as to fluid supply packages in which fluid is stored on the adsorbent and subsequently desorptively released from the adsorbent under fluid dispensing conditions, as well as fluid supply packages comprising such adsorbents, and apparatus comprising same.

As used herein, the term “dispensing conditions” means conditions which are effective to desorb fluid so that it is disengaged from an adsorbent on which it has been adsorbed, and so that disengaged fluid is dispensed from the adsorbent for use. The adsorbent may for example be disposed in a fluid supply package, in a vessel containing the adsorbent having the fluid adsorbed thereon. The dispensing conditions for desorption of the fluid from the adsorbent may include (i) heating the adsorbent to effect thermally-mediated desorption of the fluid, (ii) exposing the adsorbent to a reduced pressure condition to effect pressure-mediated desorption of the fluid, (iii) contacting the adsorbent having fluid adsorbed thereon, with a carrier fluid to effect a concentration gradient-mediated desorption of the fluid and passage of the desorbed fluid into the carrier fluid, (iv) inputting energy other than thermal energy to the adsorbent to effect desorption of the fluid, (v) contacting the adsorbent with an adsorbable fluid that acts to displace the existing adsorbed fluid so that it is desorbed, e.g., by competitive displacement at active sorptive sites on the adsorbent, and (vi) combinations of two or more of the foregoing conditions.

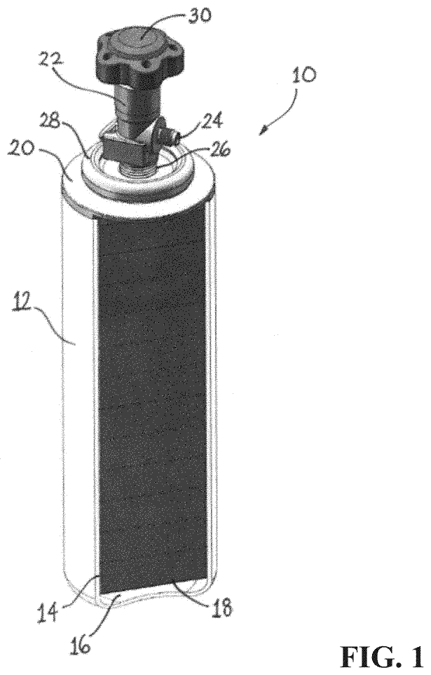

FIG. 1 is a perspective view of a fluid supply package of the present disclosure, according to one aspect thereof, in which adsorbent of the present disclosure may be disposed in a fluid storage and dispensing vessel for reversible storage of fluid thereon, in various implementations of the present disclosure.

As illustrated, the fluid supply package 10 comprises a vessel 12 including a circumscribing wall 14 and floor enclosing an interior volume 16 of the vessel in which is disposed adsorbent 18. The adsorbent 18 is of a type having sorptive affinity for the fluid of interest, and from which such fluid can be desorbed under dispensing conditions for discharge from the vessel. The vessel 12 at its upper end portion is joined to a cap 20, which may be of planar character on its outer peripheral portion, circumscribing the upwardly extending boss 28 on the upper surface thereof. The cap 20 has a central threaded opening receiving a correspondingly threaded lower portion 26 of the fluid dispensing assembly.

The fluid dispensing assembly comprises a valve head 22 in which is disposed a fluid dispensing valve element (not shown in FIG. 1) that is translatable between fully open and fully closed positions, by action of the manually operated hand wheel 30 coupled therewith. The fluid dispensing assembly includes an outlet port 24 for dispensing of fluid from the fluid supply package when the valve is opened by operation of the hand wheel 30. In lieu of the hand wheel 30, the fluid dispensing assembly may comprise an automatic valve actuator, such as a pneumatic valve actuator that is pneumatically actuatable to translate the valve in the fluid dispensing assembly between fully open and fully closed positions of the valve.

The outlet port 24 of the fluid dispensing assembly is defined by the open end of a corresponding tubular extension communicating with a valve chamber in the valve head 22 containing the translatable valve element. Such tubular extension may be threaded on its outer surface, to accommodate coupling of the fluid dispensing assembly to flow circuitry for delivery of dispensed fluid to a downstream locus of use, e.g., a fluid-utilizing tool adapted for the manufacture of a semiconductor manufacturing product such as an integrated circuit or other microelectronic device, or a fluid-utilizing tool adapted for manufacture of solar panels or flat-panel displays. In lieu of a threaded character, the tubular extension may be configured with other coupling structure, e.g., a quick-connect coupling, or it may otherwise be adapted for dispensing of fluid to a locus of use.

The adsorbent 18 in the interior volume 16 of the vessel 12 may be of any suitable type as herein disclosed, and may for example comprise adsorbent in a powder, particulate, pellet, bead, monolith, tablet, or other appropriate form. The adsorbent is selected to have sorptive affinity for the fluid of interest that is to be stored in the vessel during storage and transport conditions, and dispensed from the vessel under dispensing conditions. Such dispensing conditions may for example comprise opening of the valve element in the valve head 22 to accommodate desorption of fluid that is stored in an adsorbed form on the adsorbent, and discharge of same from the vessel through the fluid dispensing assembly to the outlet port 24 and associated flow circuitry, wherein the pressure at the outlet port 24 causes pressure-mediated desorption and discharge of fluid from the fluid supply package. For example, the dispensing assembly may be coupled to flow circuitry that is at lower pressure than pressure in the vessel for such pressure-mediated desorption and dispensing, e.g., a sub-atmospheric pressure appropriate to a downstream fluid-utilizing tool coupled to the fluid supply package by the aforementioned flow circuitry.

Alternatively, the dispensing conditions may comprise opening of the valve element in the valve head 22 in connection with heating of the adsorbent 18 to cause thermally-mediated desorption of fluid for discharge from the fluid supply package. Any other desorption-mediating conditions and techniques may be employed, or any combination of such conditions and techniques.

The fluid supply package 10 may be charged with fluid for storage on the adsorbent by an initial evacuation of fluid from the interior volume 16 of the vessel 12, followed by flow of fluid in the vessel through outlet port 24, which thereby serves a dual function of charging as well as dispensing of fluid from the fluid supply package. Alternatively, the valve head 22 may be provided with a separate fluid introduction port for charging of the vessel and the loading of the adsorbent with the introduced fluid, in the first instance.

The fluid in the vessel may be stored at any suitable pressure conditions. An advantage of using adsorbent as a fluid storage medium is that fluid can be stored at low pressure, e.g., subatmospheric pressure or low superatmospheric pressure, thereby enhancing the safety of the fluid supply package, in relation to fluid supply packages such as high pressure gas cylinders.

The fluid supply package of FIG. 1 may be used for containment of any adsorbent as disclosed herein, to provide an appropriate storage medium for the packaged fluid, and from which the fluid can be desorbed under dispensing conditions for supply by the fluid supply package to a particular locus of use or to a particular fluid-utilizing apparatus.

In one aspect, the present disclosure relates to a composition for supplying fluid for use, comprising adsorbent having fluid reversibly adsorbed thereon, wherein the adsorbent comprises material selected from the group consisting of titania, zirconia, silicalite, metal organic framework (MOF) materials, and polymer framework (PF) materials, wherein the fluid comprises fluid for manufacturing semiconductor products, flat-panel displays, solar panels, or components or subassemblies thereof, and wherein when the fluid comprises silane or disilane, the adsorbent may additionally comprise silica. In a specific aspect, the fluid comprises fluid selected from the group consisting of silane, disilane, germane, diborane, and acetylene.

In a further aspect, the disclosure relates to a fluid supply package, comprising a fluid storage and dispensing vessel containing a composition as variously described in the preceding paragraph, and a dispensing assembly configured to dispense fluid from the vessel under dispensing conditions.

In one specific aspect, the present disclosure relates to a composition for supplying silane for use, comprising silica or silicalite, having silane reversibly adsorbed thereon.

A further aspect of the disclosure relates to a method of supplying fluid for use, comprising subjecting a composition as described above, to dispensing conditions, e.g., exposing the composition to reduced pressure, heating, contact with a carrier gas, etc.

A still further aspect of the disclosure relates to a method of supplying a fluid for use, comprising dispensing the fluid under dispensing conditions from a fluid supply package as described above.

In another aspect, the disclosure relates to a method of manufacturing a product selected from the group consisting of semiconductor products, flat-panel displays, solar panels, and components and subassemblies thereof, such method comprising use of fluid desorbed from a composition as described above, in a manufacturing operation of such manufacturing method.

A still further aspect of the disclosure relates to a method of manufacturing a product selected from the group consisting of semiconductor products, flat-panel displays, solar panels, and components and subassemblies thereof, such method comprising use of fluid dispensed from a fluid supply package as described above, in a manufacturing operation of such manufacturing method.

The foregoing in reference to silane storage and dispensing involving adsorbent storage media comprising at least one adsorbent selected from the group consisting of titania, zirconia, silica, silicalite, metal organic framework (MOF) materials, and polymer framework (PF) materials, provides an effective solution to the problems attendant the use of silane. For example, although various carbon materials have been employed as adsorbent storage media on which the gases are sorptively retained, and from which they are subsequently desorbed in dispensing operation, the use of such materials as storage media for long-term storage of reactive gases such as silane is problematic, due to the reaction of such gases with impurities on the surface of the carbon and/or carbon defect sites in the adsorbent material.

The use of titania, zirconia, silica, silicalite, metal organic framework (MOF) materials, and polymer framework (PF) materials avoids such issues. The adsorbent is formed with appropriately sized pores, e.g., sub-nanometer pores of narrow pore size distribution in which silane, having a kinetic diameter of 0.37 nm, can be efficiently adsorbed, and subsequently desorbed under dispensing conditions. The adsorbent materials can be used as powders or pressed or otherwise manufactured into aggregates, beads, pellets, tablets, monoliths, or other suitable forms. The adsorbent may be constituted to provide a substantial portion of the porosity thereof in pores of less than 1 nm size, e.g., a porous adsorbent having at least 30%, 40%, 50%, 55%, 60%, 65%, 70%, 75%, 80%, 85%, 90%, 95%, or more of its porosity in pores of less than 1 nm size.

Silicalite, an all-silica zeolite, provides a desirable adsorbent medium. Silicalite-1, for example, is a hydrophobic/oleophilic, crystalline material with 10-membered rings and a pore size of ˜0.6 nm. Variants of silicalite with different pore structures/pore sizes (essentially all-silica analogs of aluminosilicate zeolites) may also be utilized to provide advantageous porosity characteristics.

In the silicalite adsorbent, pore size can be controlled by use of various techniques, such as sol gel preparation techniques, or by the choice of surfactant, auxiliary chemicals, and reaction conditions to template the growth of specific pore sizes, or vacuum deposition techniques to effectively shrink pore sizes with angstrom-level resolution. The adsorbent material formed by such wet preparation techniques is suitably dried prior to exposure to sorbable gas. Drying may be accomplished by heating the adsorbent material to elevated temperatures (typically >150° C.) in either vacuum or in a flowing inert gas. The temperature and time of dehydration will depend on the specific characteristics of the adsorbent (pore size, pore size distribution, form factor, etc.) and its storage history.

The above-described adsorbent materials may be utilized for storage and dispensing of silane or other reactive gases such as disilane, germane, diborane, acetylene, etc., at any suitable pressure (atmospheric, sub-atmospheric, or superatmospheric), depending on the quantity of gas to be stored, and at any appropriate temperature.

In one aspect, the present disclosure relates to a method of producing reduced size particles of nanoporous carbon from a nanoporous carbon starting material, the method comprising: introducing an infiltrating agent into porosity of the nanoporous carbon starting material; and activating the infiltrating agent to exert exfoliatingly effective expansive action on the porosity of the nanoporous carbon starting material, to exfoliate the nanoporous carbon starting material and produce nanoporous carbon particles of reduced size from the nanoporous carbon starting material.

The infiltrating agent may be of any suitable type, and may for example comprise acids, mixtures of acids, e.g., a sulfuric acid: nitric acid mixture, alkali metals, ammonia, organic solvents, and mixtures of two or more of the foregoing.

The activation of such infiltrating agents may be variously effected by any suitable activating conditions, e.g., by heating, by reaction with an activating agent, by exposure to an activating pressure condition, or by any other activation technique that is effective to cause the infiltrating agent to exert an expansive exfoliating action on the nanoporous carbon starting material, as hereinafter more fully described.

Such size reduction approach enables the ratio of surface area to volume to be substantially increased, to provide nanoporous carbon having broad utility in a wide variety of applications.

For example, nanoporous carbon formed as a carbon pyrolyzate of polyvinylidene chloride (PVDC) polymer or copolymer may be formed with pore (slit) sizes between 0.5 and ˜1 nm, and may have a high density (e.g., on the order of ˜1.1 g/cc), with a large micropore volume (>40%, with macropores (>5 nm) and void volume being only on the order of 10%), and a high surface area (e.g., ˜1100 m2/g). At a microscopic level, such nanoporous carbon materials consist of graphene sheets (sp2 hybridized graphite planes) that are folded and interleaved in a somewhat random orientation, yielding relatively high electrical and thermal conductivities.

Pore (slit) sizes in nanoporous carbons may be controlled within a tolerance of 0.05 nm by the choice of appropriate precursor polymer(s), e.g., PVDC or PVDC-polymethylacrylate (PMA) copolymer, appropriate selection of high temperature pyrolysis conditions, and appropriate post-processing of the carbon pyrolyzate, if required. For powders, particle sizes may illustratively be on the order of 150 μm, or more broadly in a range of from 50 μm to 300 μm, dependent on the size of the precursor polymer(s). Particle sizes required for energy storage applications are typically less than 25 microns, limited by the anode thickness (which typically is on the order of 25 microns). Thus, the successful use of nanoporous carbon in these applications may require a significant size reduction, to provide nanoscale particles of higher surface area and shorter diffusion lengths, to accommodate higher power operation.

Reduction of the particle size of hard carbons by techniques such as mechanical grinding, or planetary, ball, and/or air/jet milling is difficult, in view of the high attrition resistance, high compressive strength, and high Young's modulus of such carbons, and techniques such as ball milling are prone to producing jagged particle shapes and introducing potential contaminants from the balls. Further, the polymeric starting material that is subjected to pyrolysis may be very soft, so that grinding/milling operations may lead to particle agglomeration and/or formation of a glassy surface that blocks pores.

Graphite, as a result of its soft and non-reactive character, can be ground to micron-size particles. Despite the two-dimensional, layered structure of graphite, these small particles are essentially three dimensional. Two-dimensional graphite platelets microns in length with nanometer-scale thickness (graphene nanoparticles) can be formed using an intercalation/exfoliation/heating process. Typical molecules which readily intercalate into graphite (and other layered materials) and increase the interlayer spacing include acids and mixtures of acids, alkali metals, ammonia, organic solvents, etc. Heating these materials leads to rapid expansion/fracturing and thus significant particle size reduction. Postgrinding/milling of these “fluffy” particles then may be employed to provide a more uniform particle size distribution.

Thus, in order to reduce the particle sizes of nanoporous hard carbon without blocking pore/slit entrances, infiltration of one or more of a variety of materials (e.g., acids, mixtures of acids (for example, 4:1 sulfuric:nitric), alkali metals, ammonia, organic solvents, etc.) is employed, followed by expansion. Penetration of molecules into nanoporous carbon will be much more rapid and deeper than intercalation into graphite due to the larger pore/slit size (e.g., >0.5 nm versus 0.35 nm). In order to be effective, starting sizes for graphite intercalation/exfoliation may be on the order of 100 microns, with larger starting particle sizes requiring multiple intercalation/exfoliation steps to reach desired small particles sizes. Rapid infiltration is advantageous to minimize processing time and costs.

Rapid expansion can be effected by heating (e.g., utilizing a furnace, flame exposure, microwave, infrared, rf induction, laser, current passage through the sample, or other heating modalities, such as exothermic chemical reactions, electrochemical insertion, or sonication). The resulting temperature rise leads to increased gas pressure which exceeds the van der Waals forces holding the graphene planes together (5.9 kJ/mole). Alternatively, a chemical reaction or chemical decomposition can generate a gas (e.g., alkali metal+water→hydrogen and a metal hydroxide, or NH₄HCO₃ (aq)→NH₃ (g)+CO₂ (g)+H₂O (g)) that pushes the planes apart. It has been demonstrated that graphite can expand 200- to 300-fold during a rapid heating process.

Expansion/exfoliation may be more difficult with nanoporous carbon, however, since graphite is a two-dimensional, layered structure (sp2 bonding), as compared with a more three-dimensional structure in nanoporous carbon (with more sp3 bonding). Thus added energy or a more rapid energy ramp may be required (e.g., utilizing microwave heating or other intensive heating modality). Microwave heating may be highly advantageous in specific applications due to graphite's high cross-section for the absorption of microwave energy. Deeper penetration of intercalates in nanoporous carbon can be employed to provide enhanced exfoliation. Further heating and/or rinsing with water and/or solvents may be utilized to fully remove any remaining intercalates. In consequence of the three-dimensional structure of nanoporous carbon, small three-dimensional particles can be achieved. Post-process grinding or milling and/or sieving may be employed, depending on the final particle size, particle size distribution, and particle shape desired.

In addition to a reduced particle size, the infiltration and activation exfoliation process may be carried out to achieve a decrease in density (interstitial space between particles), an increase in surface area, a decrease in thermal and electrical conductivity, an increase in pore (slit) size, and more edge defects. Further chemical treatment may be employed to control the material properties, e.g., hydrophobicity, hydrophilicity, surface passivation, and/or doping, as desired for specific application of the carbon material.

The disclosure thus contemplates reduction of particle size of hard nanoporous carbons to provide high surface area small-sized carbon particles useful for fluid storage and dispensing applications, and for energy storage applications, in which significant size reduction of the nanoporous carbon may be carried out to achieve higher surface area and shorter diffusion lengths.

In the process of the present disclosure, including the use of an infiltrating agent that is introduced into porosity of the nanoporous carbon and then activated to exert exfoliatingly effective expansive action on the porosity of the nanoporous carbon, to exfoliate the nanoporous carbon and produce particles of reduced size from the nanoporous carbon, the nanoporous carbon starting material may have porosity including pores of any suitable character. In various embodiments, at least 30% of the porosity of the nanoporous carbon starting material is comprised by pores of from 0.5 nm to 1 nm size. In other embodiments, at least 40%, 50%, 55%, 60%, 65%, 70%, 75%, 80%, 85%, 90%, 95%, or even higher percentages of the porosity may be comprised by pores of such 0.5 nm to 1 nm size. The pores may be slit-shaped or have other shape characteristics and may vary in depth, tortuosity, and other pore characteristics.

The infiltrating agent may be of any suitable type that is able to be activated in situ in the porosity of the nanoporous carbon to produce rapid expansion of pores yielding the exfoliation to generate reduced size particles from the nanoporous carbon starting material. Infiltrating agents potentially useful for such purpose in specific embodiments of the disclosure include, without limitation: acids as well as mixtures of acids, e.g., 4:1 sulfuric acid: nitric acid; alkali metals; ammonia; organic solvents; etc. The infiltrating agent is desirably selected for its ability to rapidly and deeply penetrate the nanoporous carbon starting material. The nanoporous carbon starting material may for example have a piece size in a range of from 100 to 200 μm in specific embodiments. In other embodiments, the nanoporous carbon starting material may have an average piece size in a range of from 100 to 200 μm, although larger or smaller piece sizes, or average piece sizes, may be employed, with larger piece sizes being subjected to repeated treatments with the infiltration agent, activation thereof, and exfoliative size reduction, to achieve the desired reduced size character of nanoporous carbon product particles. As indicated previously herein, rapid infiltration of the infiltrating agent into porosity of the nanoporous carbon is desirable to effect minimization of processing time and reduction of associated cost. In this respect, infiltration velocity can be readily empirically determined, within the skill of the art, based on the disclosure herein.

The reduced size particles of nanoporous carbon produced by the above-described method may have any suitable size or size distribution of particles. In specific embodiments, the reduced size particles of nanoporous carbon produced by such method may for example comprise particles of size in a range of from 5 μm to 50 μm, or a range of from 10 μm to 40 μm, or a range of from 12 μm to 30 μm, or a range of from 15 μm to 25 μm, or other range suitable for the application for which the reduced size particles are intended.

As previously described, the activation of the infiltrating agent may be carried out in any suitable manner that is effective to cause the exfoliative action by the activated infiltrating agent in the porosity of the nanoporous carbon. This may for example involve input of energy to the infiltrating agent, so that rapid expansion can occur as a result of heating, e.g., in a furnace, by flame exposure, microwave radiation exposure, infrared radiation exposure, radiofrequency (RF) induction, laser impingement, passage of current through the nanoporous carbon, or in other suitable manner effecting heating of the infiltrating agent. Alternatively, the infiltrating agent may be activated to undergo exothermic chemical reaction or electrochemical insertion by corresponding activation techniques. As another alternative, the nanoporous carbon may be subjected to sonication to activate the infiltrating agent so that expansive exfoliating action is initiated. In other embodiments, activation of the infiltrating agent may involve selective change of pH, pressure, and/or temperature, contact of the infiltrating agent with an activating agent therefor, or other action causing the infiltrating agent exert the expansive exfoliating action on the nanoporous carbon starting material. It will therefore be understood that a wide variety of infiltrating agents and corresponding activation techniques may be employed.

Post-exfoliation processing of the reduced size nanoporous carbon particles may be required to remove the infiltrating agent and/or its reaction byproducts, residual activating agents, etc. Such processing may involve further heating of the reduced size nanoporous carbon particles and/or rinsing of same with water and/or other solvents to remove extraneous material from the porosity of the exfoliated nanoporous carbon particles. Sieving or other post-exfoliation processing may be required for recovery of particles in a predetermined particle size range or of a predetermined particle size distribution. Post-exfoliation processing may further include chemical treatment to control hydrophobicity and hydrophilicity of the nanoporous carbon, and/or to effect surface passivation or import other useful properties to the product nanoporous carbon particles. The nanoporous carbon particles may be doped in post-exfoliation processing to improve physicochemical properties thereof.

The infiltration and exfoliation process thus enables production of reduced size nanoporous carbon without blockage of porous/slit entrances of the porosity. Additional changes in properties of the nanoporous carbon resulting from the infiltration and exfoliation process may include, in specific embodiments, decreased density as a result of increased space between particles, increased surface area, decreased thermal and electrical conductivity as a result of increased particle/particle interfaces to scatter electrons and phonons, and increased pore/slit size from the expanding infiltrating agent.

Another aspect of the present disclosure relates to nanoporous carbon particles produced by such method of producing reduced size particles of nanoporous carbon, as exfoliate particles.

A further aspect of the present disclosure relates to a fluid supply package comprising a fluid storage and dispensing vessel coupled with a valve head assembly arranged for dispensing fluid from the vessel under fluid dispensing conditions, wherein the fluid storage and dispensing vessel comprises nanoporous exfoliate carbon particles produced by the exfoliation method of the present disclosure.

The disclosure in another aspect relates to a method of making a carbon pyrolyzate adsorbent having predetermined porosity. In such method, a multi-layered, e.g., co-layered, material is formed including at least one layer of a pyrolyzable starting material, e.g., a PVDC-based pyrolyzable starting material including PVDC or PVDC copolymer and any additives that are employed to enhance or support the carbon pyrolyzate adsorbent produced in the method. The multi-layered material further includes at least one layer of an evanescent material that is eliminated or nearly eliminated during the process of pyrolyzing the pyrolyzable starting material in the multilayer structure at elevated temperature, which may include an inert gas environment. The elimination of the evanescent material may be effected by volatilization of such material during the pyrolysis process, or other modality of elimination from the pyrolyzing multi-layer structure.

The multi-layer structure in its simplest form comprises a co-layer structure including a single layer of the pyrolyzable starting material and a single layer of the evanescent material. Additional layers of the respective materials may be added as desired. The thicknesses of the respective layers in the multi-layer structure may be varied in relation to one another, to provide a desired proportion of the evanescent material to the pyrolyzable starting material, which in turn will provide a desired porosity in the carbon pyrolyzate adsorbent produced in the method.

Thus, the type and relative thickness of the pyrolyzable starting material and evanescent material layers in the multi-layer structure, and the conditions of the pyrolysis process, will be determinative of the porosity (pore volume, pore sizes, pore size distribution, etc.) and the density of the carbon pyrolyzate adsorbent, and carbon pyrolyzate adsorbent of a predetermined porosity and density character can be achieved by empirical assessment without undue experimentation, based on the disclosure herein.

In general, high density carbon pyrolyzate adsorbent may be achieved by a correspondingly high content of pyrolyzable starting material in the multi-layer structure, in relation to the evanescent material content. This may be achieved by a substantially greater thickness of the pyrolyzable starting material layer in the multi-layer structure, as compared to the evanescent material layer thickness. Conversely for a low density carbon pyrolyzate adsorbent, having high void volume, a lower thickness of the pyrolyzable starting material layer in relation to the thickness of the evanescent material layer may be employed. Such high void volume carbon pyrolyzate adsorbents may be employed in applications in which there is a need for low pressure drop in the contacting of adsorbable fluid with the adsorbent, as opposed to other applications in which pressure drop considerations are not predominant.

It will be recognized that the multi-layer structure may comprise a single layer of pyrolyzable starting material and a single layer of evanescent material, or that multiple layers of one or both of such materials may be employed in the multi-layer structure.

The multi-layer structure, once formed, then is folded at least one time, and preferably more than one time, to form a multi-layer assembly structure. By the initial provision of a multi-layer structure of suitable length, the folding assembly process can be utilized to achieve a large number of layers through repeated multiplying folding and reforming operations. When the folding assembly process is completed, the multi-layer assembly structure can then be wrapped and/or laid up in thicker structures, e.g., plates or blocks, and then pyrolyzed to convert the pyrolyzable starting material to nanoporous carbon, to yield the desired carbon pyrolyzate adsorbent. Such folding and reforming process may be automated, and may be combined with intermediate stretching, spreading, or thinning operations in which the areal extent of the folded and reformed multilayer structure is increased and the thickness of constituent layers in the structure is decreased.

Alternatively, the multi-layer structure, once formed, may be cut into smaller lengths or portions, of a same or similar size, and the cut portions then may be subjected to intermediate stretching, spreading, or thinning operations in which the areal extent of the composite multilayer structure is increased and the thickness of constituent layers in the structure is decreased, followed by stacking of the areally expanded layers further, and subsequent cutting, areal expansion, and stacking operations, repeated until a desired multi-layer assembly structure is achieved. As a still further alternative, the multi-layer structure, instead of being subjected to sequential cutting, areal expansion, and stacking operations, may be carried out with areal expansion of the composite multilayer structure after the stacking operation but before the cutting operation, so that the sequence of process operations involves successive stacking, areal expansion, and cutting operations.

As yet another option, the multi-layer structure or a subsequent composite multilayer structure formed by sequential cutting, areal expansion, and stacking operations, or by sequential stacking, areal expansion, and cutting operations, may be subjected to folding operations. Likewise, the initially described folding operations may be carried out with additional sequential cutting, aerial expansion, and stacking operations, and/or sequential stacking, areal expansion, and cutting operations.

All of the above-described transitional processing steps performed on the initial multi-layer structure to convert it to a multi-layer assembly structure for subsequent pyrolysis, or a selected one or ones thereof, may be utilized, in any suitable permutation or combination when multiple such operations are performed, to produce a carbon pyrolyzate adsorbent of the desired character.

The evanescent material provided in the multi-layer structure may be appropriately selected to have a melting point and other properties that accommodate the folding assembly process, but that is thermally unstable in the pyrolysis operation, such that the evanescent material becomes degraded and leaves minimal residue when the pyrolyzable starting material is converted to the carbon pyrolyzate adsorbent. In this manner, the evanescent material may be selected so that the layers of pyrolyzable starting material are converted to high density sheets of carbon in the carbon pyrolyzate product, to produce a pyrolyzate product comprising a robust stack of parallel micro-sheets of hard carbon adsorbent. By maintaining the multi-layer assembly structure in a flat conformation during pyrolysis, adsorbent plates can be formed having beneficial thermal properties and permeability.

The disclosure in this respect contemplates tailoring of carbon layer thickness and spacing in the carbon pyrolyzate product to produce adsorbent with molecular sieving characteristics.

The evanescent material may be of any suitable type, and may for example comprise any sublimable solid (organic or inorganic) material with appropriate thermal properties, or a viscous slurry material with a relatively low boiling point. Illustrative evanescent materials include, without limitation, ammonium carbonate, ammonium chloride, terephthalic acid, naphthalene, alkyl naphthalenes, napthoquinone, camphor, and the like.

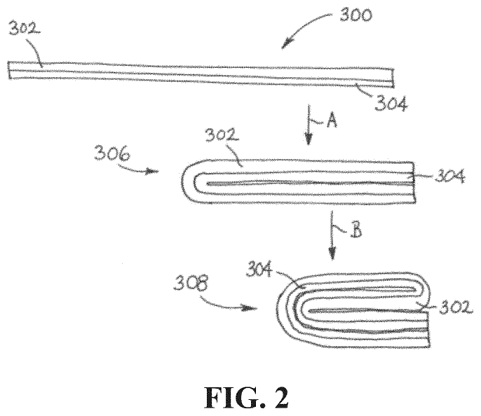

Referring now to the drawings, FIG. 2 shows a process sequence, in which a multi-layer structure is converted to a multi-layer assembly structure by successive folding steps.

The multi-layer structure 300 comprises a layer of pyrolyzable starting material 304, and a layer of evanescent material 302 deposited thereon. This multi-layer structure 300 then is folded in a folding operation indicated by arrow A to form the folded multi-layer intermediate structure 306, which then is folded in a further folding operation indicated by arrow B to form the multi-layer assembly structure 308. The multi-layer assembly structure 308 may then be subjected to pyrolysis operation, in which the evanescent material layer 302 is volatilized, or otherwise removed during the pyrolysis operation, to yield a carbon pyrolyzate as the carbon adsorbent product, having desired void volume and porosity characteristics. The pyrolysis operation may be conducted that any suitable pyrolysis conditions, and may for example be carried out in progressive fashion involving temperature ramping from an ambient starting temperature to a desired elevated pyrolysis temperature, e.g., in a temperature range of from 600° C. to 1000° C., with a pyrolysis processing time that may variously range from 1 to 7 days, or longer, depending on the specific time-temperature schedule and product properties desired in the pyrolysis operation.

FIG. 3 is a schematic representation of a sequential spreading, cutting, and stacking process that is utilized to convert a starting multi-layer structure to a multi-layer assembly structure.

As illustrated in FIG. 3, the starting multi-layer structure 320 comprises a layer of pyrolyzable starting material 324 and a layer of evanescent material 322 deposited thereon. Such multi-layer structure is subjected to facial compression indicated by arrows P on its respective top and bottom faces, so that the spreading operation indicated by arrow 330 results in a multi-layer structure that is expanded in areal extent, as illustrated. The areally extended multi-layer structure then is processed by a cutting operation indicated by arrow 332, along the cut line indicated by dashed line C, to form cut multi-layer sections that are stacked as indicated by arrow S in the stacking operation indicated by arrow 334 to form an intermediate multi-layer stack 342.

The intermediate multi-layer stack 342 is subjected to facial compression indicated by arrows P on its respective top and bottom faces in a spreading operation indicated by arrow 336, to form the areally expanded intermediate multi-layer stack 342 that then is cut indicated by dashed line C in a cutting operation indicated by arrow 338. The resulting cut multi-layer sections 346 and 348 that are stacked as indicated by arrow S in a stacking operation indicated by arrow 340 to form the multi-layer assembly structure 350. The multi-layer assembly structure 350 that may be pyrolyzed to form the carbon pyrolyzate adsorbent product. The pyrolysis operation may be carried out in any suitable manner, to dissipate or otherwise remove the evanescent material from the multi-layer assembly structure to form the carbon pyrolyzate adsorbent having a suitable porosity character, density, and other desired characteristics.

It will be recognized that the spreading, cutting, and stacking process described in connection with FIG. 3 is of an illustrative character only, and that the spreading, cutting, and stacking steps of the illustrated methodology may alternatively be carried out in other sequences, and with other numbers of repetitive cycles, to form multi-layer assembly structures of any desired types and properties.

Thus, the disclosure in one aspect contemplates a method of forming a multi-layer assembly structure that is pyrolyzable to form a carbon pyrolyzate adsorbent, such method comprising forming a multi-layer structure comprising at least one layer of a pyrolyzable starting material and at least one layer of an evanescent material, and processing the multi-layer structure to form a multiplicated multi-layer structure including an increased number of layers of pyrolyzable starting material and evanescent material in relation to the multi-layer structure prior to such processing, as the multi-layer assembly structure that is pyrolyzable to form the carbon pyrolyzate adsorbent.

The processing of the multi-layer structure to form a multiplicated multi-layer structure in the foregoing process may comprise folding of the multi-layer structure, e.g., as described in FIG. 2, or process steps comprising spreading, cutting, and stacking operations, performed in any suitable sequence, e.g., the spreading/cutting/stacking sequence illustratively described in connection with FIG. 3, or any other processing operation(s), e.g., cutting alone, producing the multiplicated multi-layer structure, as the multi-layer assembly structure that is pyrolyzable to form the carbon pyrolyzate adsorbent.

In one embodiment, the processing of the multi-layer structure to form a multiplicated multi-layer structure comprises winding up layers of the pyrolyzable starting material and layers of the evanescent material to form the multiplicated multi-layer structure as a roll. In another embodiment, the processing of the multi-layer structure to form a multiplicated multi-layer structure comprises interposing a screen impregnated with the evanescent material between layers of the pyrolyzable starting material. In a further embodiment, the processing of the multi-layer structure to form a multiplicated multi-layer structure comprises applying a layer of the evanescent material to a layer of the pyrolyzable starting material; the fabrication method then may optionally further include winding up the layer of pyrolyzable starting material having the layer of evanescent material applied thereto, to form the multiplicated multi-layer structure as a roll.

The evanescent material in any of such embodiments or otherwise within the broad methodology herein disclosed, may contain non-evanescent material that upon evanescence of the evanescent material constitutes spacer material in the carbon pyrolyzate adsorbent.

The non-evanescent material in the broad practice of the present disclosure may comprise at least one material selected from the group consisting of carbon nanotubes, graphene flakes, carbon whiskers, carbon black, bucky balls, aluminosilicate powders, silicon carbide particles, zeolitic materials, metal organic framework (MOF) materials, and metal and metal alloy bodies.

Such multi-layer assembly structure then may be pyrolyzed to evanesce the evanescent material while pyrolyzing the pyrolyzable starting material in the pyrolyzable starting material layers in the multi-layer assembly structure, to yield the carbon adsorbent as a pyrolyzate product of desired character. The carbon pyrolyzate adsorbent may be employed to form a carbon pyrolyzate article, as hereinafter more fully disclosed, and such carbon pyrolyzate article may be employed to form a fluid filtration, purification, or separation apparatus, as also hereinafter more fully disclosed.

Thus, the disclosure contemplates preparation of multi-layered structures comprising evanescent material and pyrolyzable material in constituent layers, which are then pyrolyzed to yield microporous carbon pyrolyzate adsorbents of tailored porosity and/or density.

In such manufacturing process, the multi-layered material can be formed and stretched, and subjected to other processing steps, in a continuous fashion. For example, the process may be a roll-to-roll process, in which a multi-layered multi-component jelly roll structure is produced.

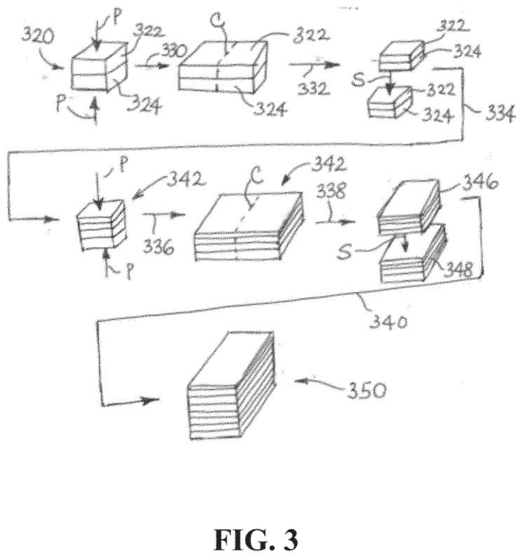

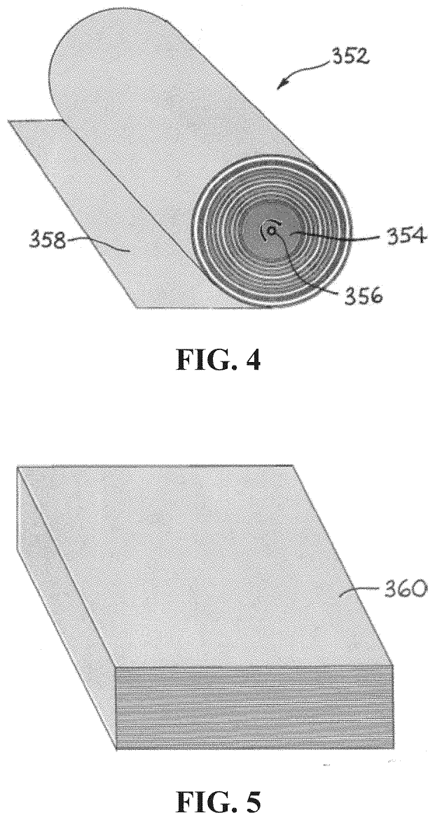

FIG. 4 is a schematic perspective view of a roll 352 in which a multi-layered sheet 358 has been formed on a cylindrical core body 354 mounted on rotatable spindle 356. The rolled multi-layered, multi-component material can subsequently be sliced off the roll in any number of ways, to yield smaller rolls or blocks or sheets upon flattening. FIG. 5 is a perspective view of such a block 360, formed from a multi-layered sheet such as is shown in FIG. 4. These sheets or blocks can then be processed as multi-layered monolith blocks or sheets. Upon pyrolysis, the sheets or blocks may have desired porosity and/or density, and they can be made to have very different properties of conductivity, permeability, strength in one axial direction versus another due to the layering and orientation of hard carbon (near-graphitic) planes. Alternatively, they can be cut or punched into pieces of desired size and shape.

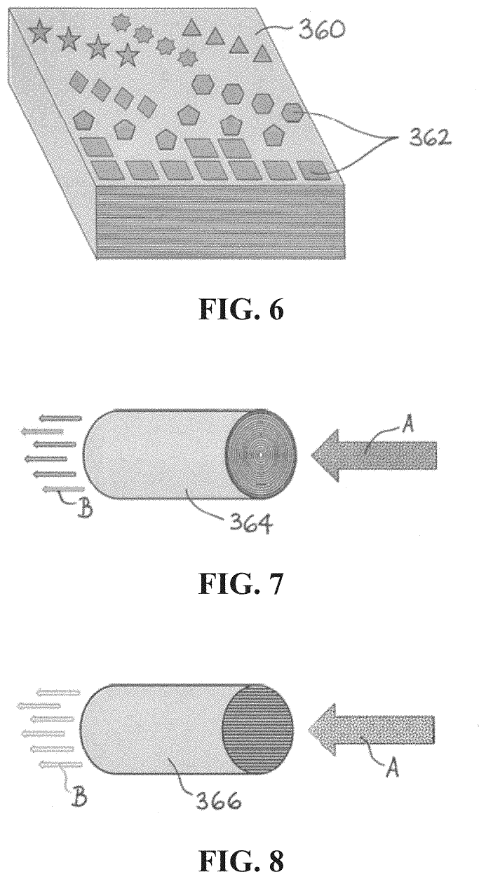

FIG. 6 is a perspective schematic view of the block 360 shown in FIG. 5, in which a variety of shapes 362 can be cut for corresponding production of discrete pieces of the multi-layer material. Such multi-layer pieces then can be pyrolyzed.

In addition, the jelly roll multi-layer, multi-component article including an evanescent layered species combined with a pyrolyzable hard carbon precursor material can be employed to yield a tailored microporous adsorbent structure having utility as a gas filtration or gas separation article, in which particle filtration and impurity capture may be accomplished with minimum pressure drop across the pyrolyzate article so that high fluid flow rates can be used in efficient gas filtration and gas separation applications.

FIG. 7 is a perspective schematic view of a pyrolyzate gas-contacting article produced from a jelly roll multi-layer, multi-component article including evanescent layers and pyrolyzable hard carbon precursor material layers, in which the pyrolysis has effected removal of the evanescent material to produce a pyrolyzate gas-contacting article having fluid flow passages formed by the removal of the evanescent material from the jelly roll precursor article. By such structure, fluid flowed in the direction indicated by arrow “A” is flowed longitudinally through the passages and contacts the carbon pyrolyzate material in the article, with the resulting filtered and/or impurity-reduced fluid being discharged from the article in the direction indicated by arrows “B”.

Accordingly, the present disclosure contemplates carbon pyrolyzate articles including flow passages therein, wherein the carbon pyrolyzate in the article is of anisotropic character in consequence of the processing of the jelly roll precursor article. The anisotropy may comprise anisotropic property/properties selected from porosity, density, conductivity, permeability, etc.

It will be appreciated that instead of the jelly roll precursor article, filtration and gas separation articles may also be formed from multi-laminate precursor articles of other geometries and conformations, e.g., planar, arcuate, etc., as may be desired or appropriate in a given end use application.

In the jelly roll precursor article, or other multi-layer precursor articles of the above-describe type, as intended for carbon pyrolyzate product articles through which fluid may be flowed, the “lay-up” process of superimposing or otherwise aggregating respective layers of pyrolyzable and evanescent materials may optionally include incorporation in the precursor article of non-evanescent spacer elements, to achieve suitable open space between the hard carbon pyrolyzate layers, so that the product article has enough gas flow conductance to be useful as a through-flow filter or separation structure. Such non-evanescent spacer elements could for example comprise metal particles, e.g., bb's or ball bearings, that are dispersed in an evanescent resin, and remain behind his spacers after the evanescent material is volatilized or otherwise removed from the pyrolyzed or pyrolyzable material, so that the hard carbon pyrolyzate layers are spaced apart by the residual spacer elements. The spacer elements if formed of metal have the advantage of high thermal conductivity so that they also assist to isothermalize the entire multi-laminate matrix of the carbon pyrolyzate product article in subsequent use.

More broadly, the spacer elements in the product article may be formed from a microporous pyrolyzate carbon powder as filler material in the evanescent layers of the multi-layer composite precursor article. The spacer elements may also be formed of materials such as carbon nanotubes, graphene flakes, carbon whiskers, carbon black, buckyballs, alumina-silicate powders, silicon carbide particles, zeolitic materials, metal organic framework (MOF) materials, metal or metal alloy bodies, or other materials that will survive the thermal pyrolysis process in the presence of the gaseous byproducts of the pyrolysis operation. The residual spacer materials may act as inert physical spacers or as additives that lend further properties or performance characteristics, such as electrical conductivity, thermal conductivity, sorptive capacity for specific gases or impurities, scavenging character, etc., to the product carbon pyrolyzate article.

As an alternative to the provision of spacer elements by disposing spacer materials in the evanescent medium that is used to form the multi-layer precursor article in the first instance, screen or grid members may be employed, which are impregnated with the evanescent material, e.g., by roller coating or other application technique, so that the openings in such foraminous elements are filled with the evanescent material and incorporated in the multi-layer precursor article in the lay-up operation. The subsequent volatilization of the evanescent material in the laid-up laminate will leave the screen or grid as the spacer between the hard carbon layers. In this respect, the dimensions of the longitudinal and transverse strands of the screen can be tailored appropriately to achieve a proper final fluid flow conductance for the carbon pyrolyzate product article. Similar dimensioning of grid elements may be employed to achieve desired conductance in the product article.

Considering again the multi-layer precursor material that is subjected to pyrolysis, it will be appreciated that such multi-layer precursor material may be cut, formed, or fashioned into a variety of potential shapes prior to pyrolysis, to produce specific desired shapes of product articles, e.g., circular, square, or other geometrically regular or irregular shapes.

FIG. 8 is a perspective schematic view of a gas-contacting carbon pyrolyzate article 366 of a type that has been formed by layering of sheets of pyrolyzable material and sheets of evanescent material, followed by punching, cutting, or other forming operations, to yield a cylindrical article in which the adjacent sheets are parallel to one another, extending longitudinally in the cylindrical article, so that subsequent pyrolysis removes the evanescent material in the alternating sheets thereof, to yield flow passages of generally rectangular cross-section, transverse to the longitudinal axis of the carbon pyrolyzate article. As illustrated in FIG. 8, influent fluid, flowed in the direction indicated by arrow “A”, flows through such rectangular cross-section flow passages, contacting the carbon pyrolyzate layers for adsorptive removal of impurities, filtration of solid particles, and/or other contacting operations, with the resulting processed fluid being discharged at the distal end of the product article in the direction indicated by arrows “B.”

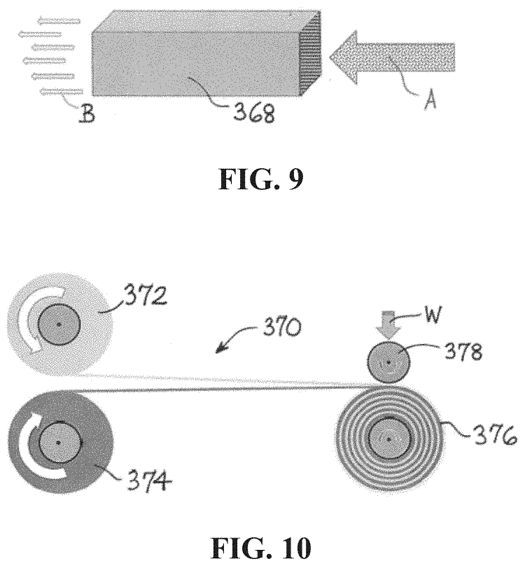

FIG. 9 is a perspective schematic view of a gas-contacting carbon pyrolyzate article 368 formed of alternating layering of sheets of pyrolyzable material and sheets of evanescent material, in the manner of the carbon pyrolyzate article 366 of FIG. 8, but having a square cross-section, rather than the circular cross-section in the article of FIG. 8. The gas-contacting carbon pyrolyzate article 368 may be deployed in an array of such articles, wherein each of the constituent articles is in abutting relationship to at least one other of such articles, to provide an assembly thereof with which gas may be contacted at appropriate volumetric flow rate and superficial velocity to conduct the desired fluid contacting operation. The direction of fluid flow in FIG. 9 is indicated by the influent fluid directional arrow “A” and the discharged fluid directional arrows “B.”

FIG. 10 is a schematic elevation view rendering of a process system 370 comprising feed rolls 372 and 374 of pyrolyzable material and evanescent material, respectively, wherein the feed rolls are driven in the direction indicated by the associated arrows so that respective sheets of pyrolyzable material and evanescent material are received on the take-up roll 376, to provide a jelly roll confirmation precursor article that may be subjected to pyrolysis to form the carbon pyrolyzate article of the type shown in FIG. 7. The take-up roll 376 may have associated there with a compression roll 378 that is spring biased or otherwise operative to exert force in the direction indicated by arrow “W” to assure that the respective layers of pyrolyzable and evanescent material are in full areal contact with one another, without the presence of air bubbles or other void pockets between such layers as taken up on the take-up roll 376.

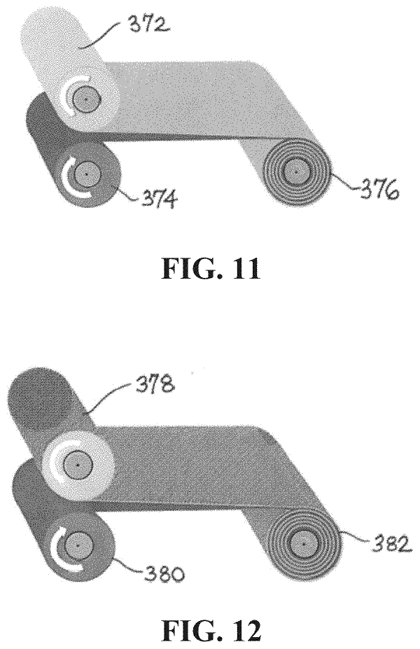

FIG. 11 is a simplified schematic perspective view of the process system of FIG. 10, showing the respective rolls 372, 374, and 376 thereof.

FIG. 12 is a simplified schematic perspective view of a similar process system to that shown in FIG. 11, but wherein top roll 378 is a feed roll of screen, and bottom roll 380 is a feed roll of pyrolyzable material, so that the jelly roll conformation of the resulting wound precursor article 382 is made up of alternating layers of screen and pyrolyzable material.

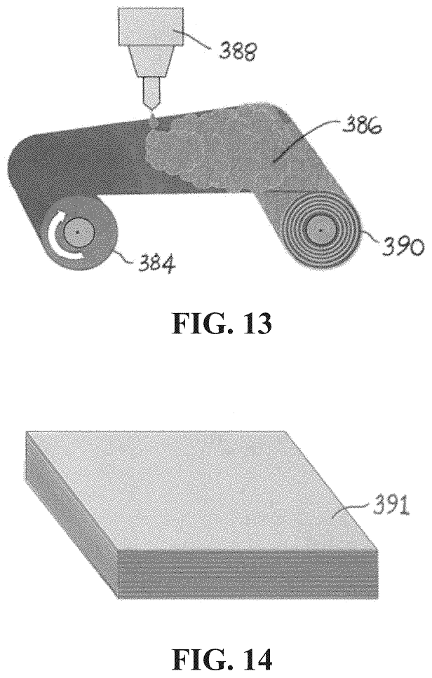

FIG. 13 is a simplified schematic perspective view of another process system, in which a feed roll 384 of pyrolyzable material provides a sheet of such pyrolyzable material that is taken up on the pyrolyzable article roll 390, and wherein the sheet of pyrolyzable material intermediate the feed and take-up rolls receives a coating 386 of evanescent material from coating material dispenser 388. The resulting jelly roll conformation precursor article then can be longitudinally severed to form a block laminate 391 as shown in FIG. 14, which is pyrolyzable to form a product carbon pyrolyzate article having passages therein deriving from the evanescent material that has been removed in the pyrolysis operation.

It will be appreciated that the formation of the multi-layer precursor article can be carried out with a multiplicity of differing material layers.

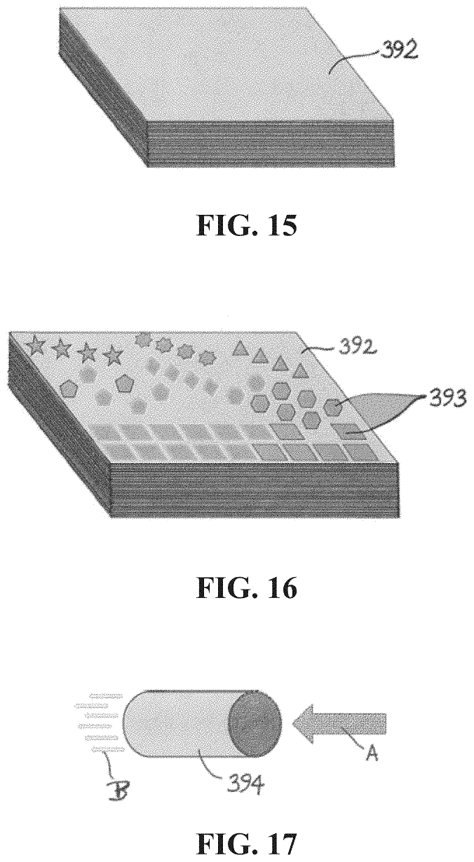

FIG. 15 is a perspective view of a multi-layer pyrolyzable article 392 comprising three different types of layers. FIG. 16 is a perspective view of such multi-layer pyrolyzable article 392, from which may be cut a multiplicity of shaped pieces 393, as illustrated.

FIG. 17 is a perspective schematic view of a carbon pyrolyzate fluid-contacting article 394 according to another embodiment of the disclosure, as manufactured from a jelly roll conformation precursor article including cylindrically wound layers of evanescent material-impregnated screen alternating with layers of pyrolyzable material, with the precursor article having been subjected to pyrolysis conditions to form fluid passages between the carbon pyrolyzate laminae in which the screen, formed of a material unaffected by the pyrolysis operation, serves as a spacer between the carbon pyrolyzate layers. The path of fluid flow through the article 394 as shown by the influent fluid directional arrow “A” and the fluid discharge direction is indicated by the discharge arrows “B.”

The disclosure relates in another aspect to a method of making a carbon pyrolyzate adsorbent, comprising blending a pyrolyzable starting material with metal filaments, e.g., iron filaments, to form a composite pyrolyzable starting material, pyrolyzing the pyrolyzable starting material to form a composite pyrolyzate, and contacting the composite pyrolyzate with a removal agent that is effective to at least partially remove the metal filaments from the composite pyrolyzate, to form the carbon pyrolyzate adsorbent.

This method has the advantage that the pore size and porosity characteristics can be closely controlled by the dimensional characteristics of the metal filaments. The removal agent may be of any suitable type that is effective for at least partial removal of the metal filaments from the composite pyrolyzate. In specific embodiments, the removal agent may comprise an acid, such as hydrochloric acid, sulfuric acid, nitric acid, or the like, which is effective to chemically react with the metal filaments to achieve removal thereof from the composite pyrolyzate. Alternatively, the removal agent may comprise a solvent that is effective to dissolve or leach the metal filaments from the composite pyrolyzate.

The amount of the metal filaments employed to form the carbon pyrolyzate may be empirically determined by simple experiment involving formulation of samples of varying metal filament content, and pyrolysis of such samples, and removal agent treatment thereof, to determine the concentration of metal filaments to be blended with the pyrolyzable starting material to achieve the desired porosity and permeability characteristics for the final carbon pyrolyzate adsorbent product.

In embodiments where iron filaments are employed as the metal filaments, iron content of the processed pyrolyzate can easily be measured by density or magnetic susceptibility instruments, so that a removal agent and contacting protocol are readily determinable to achieve essentially complete, e.g., 95-100%, metal filament removal from the composite pyrolyzate.

The disclosure further contemplates carbon pyrolyzate adsorbent that is formed by such method.

The disclosure in another aspect relates to enhancement of purity of dispensed gas from an adsorbent-based gas supply package, and to approaches for fabricating the gas supply package to achieve such purity enhancement.

In one aspect, the disclosure relates to a process for fabricating a gas supply package, comprising pyrolyzing a pyrolyzable starting material in a pyrolysis furnace to form a carbon pyrolyzate adsorbent that is discharged from the pyrolysis furnace at a discharge locus, and packaging the carbon pyrolyzate adsorbent at the discharge locus in a gas storage and dispensing vessel including a dispensing assembly, to form the gas supply package.

The pyrolyzable starting material may be in the form of powder, granules, pellets or monolithic forms such as bricks, blocks, boules, cylindrical discs, or a combination of two or more of such forms, or other suitable shape and form of the starting material, so that a corresponding form or forms is/are achieved in the carbon pyrolyzate adsorbent. The disclosure also contemplates the concurrent use of two or more sizes of a same form of the pyrolyzable starting material, to form the corresponding carbon pyrolyzate adsorbent.

The gas storage and dispensing vessel may be of cylindrical form or other vessel geometry. In one embodiment, the gas storage and dispensing vessel is of cylindrical form and the carbon pyrolyzate adsorbent is in the form of cylindrical discs that are introduced into the interior volume of the gas storage and dispensing vessel, to define a stacked array of such cylindrical discs, wherein each of such discs has a diameter that closely approaches the internal diameter of the vessel, e.g., is within 1.5 cm of such internal diameter, to maximize the volume in the vessel occupied by the adsorbent, and wherein each successive pair of cylindrical discs in the stack abuts one another in face-to-face abutting relationship.

The fabrication of the gas supply package may be carried out in a fabrication facility that comprises an enclosure in which the pyrolysis furnace is disposed. The enclosure may additionally comprise a fill station in the discharge locus of the pyrolysis furnace, optionally further including an activation zone in the pyrolysis furnace, with the fill station being arranged for packaging of the carbon pyrolyzate adsorbent in the gas supply package. The enclosure may be supplied with inert gas(es) and/or other gas(es) conducive to the manufacturing process. The carbon pyrolyzate adsorbent may be packaged in the gas supply package under an inert atmosphere (e.g., comprising one or more ofnitrogen, helium, argon, xenon, and krypton) or in a reducing atmosphere of hydrogen, hydrogen sulfide, or other suitable gas, or a combination of inert gas and reducing gas. The manufacturing process may be carried out in separate contiguous zones of a manufacturing facility, wherein each is provided with a different ambient gas environment, to facilitate respective pyrolysis, adsorbent loading of the gas storage and dispensing vessel, and securement of the gas dispensing assembly to the gas storage and dispensing vessel.

The dispensing assembly may comprise a valve head containing a valve element that is translatable between fully open and fully closed positions by a valve controller or actuator. The valve head may include a single port utilized for gas filling and gas dispensing, or the valve head may alternatively include separate dedicated gas fill and gas dispensing ports. The valve head may be configured for manual valve control, e.g., by a hand wheel or similar mechanical structure, or the valve head may be configured for actuation and modulation of the valve element by a valve actuator, e.g., a pneumatic valve actuator.

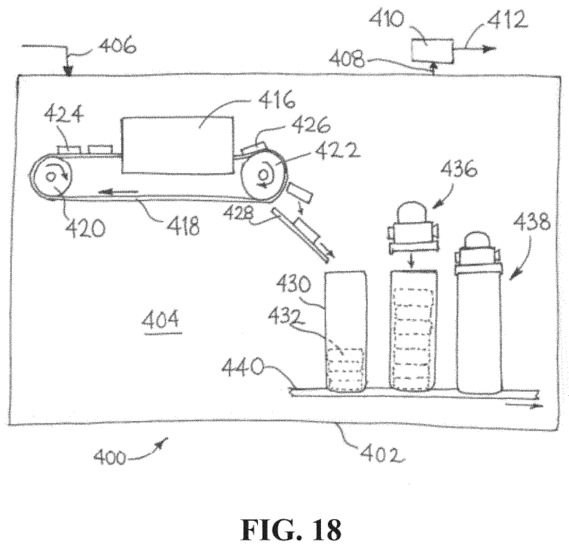

FIG. 18 is a schematic representation of a fabrication facility for manufacturing a gas supply package according to one aspect of the disclosure.

As shown in FIG. 18, a fabrication facility 400 may include a process facility enclosure 402 in which is disposed a pyrolysis furnace 416, in which pyrolyzable starting material articles 424 are pyrolyzed to form carbon pyrolyzate adsorbent articles 426, with the pyrolyzable starting material articles being disposed on a conveyor belt 418 disposed on rotatable rollers 420 and 422, one or both of which is driven by a suitable motive driver (not shown in FIG. 13).

The process facility enclosure 402 may be provided with an appropriate atmosphere within the enclosure by gas supply line 406, which may be coupled with a suitable source of the gas employed to establish the atmosphere in the enclosure 402. The gas may be an inert gas, such as nitrogen, argon, krypton, etc., or a reducing gas of appropriate character.

The carbon pyrolyzate adsorbent articles 426 resulting from the pyrolysis in pyrolysis furnace 416 are discharged from the furnace at a discharge locus containing slide 428. The discharged adsorbent articles 426 thus gravitationally slide down the slide structure into a gas storage and dispensing vessel 430 positioned on moving conveyor belt 440, so that the successively introduced adsorbent articles forms and adsorbent articles stack 432 in the interior volume of the vessel. The vessel once filled with a stack of suitable height therein is translated to an assembly station where a valve head dispensing assembly 436 is mated with and secured to the vessel, to form the gas supply package. The valve head dispensing assembly 436 may be secured to the vessel 430 in any suitable manner, and may for example be mechanically joined to the vessel by suitable mechanical fasteners, or alternatively the valve head assembly and the vessel may be secured by welding along the seam at their juncture, or the securement of the valve head assembly in vessel may be effected in any other suitable manner.

The process facility enclosure 402 may be equipped with a gas discharge line 408 for gas that is withdrawn from the interior volume 404 of the enclosure 402 by a motive fluid driver 410, which may comprise an exhaust fan, blower, eductor, or the like, with the gas being discharged to the atmosphere or other disposition in vent line 412. The discharged gas may for example be processed in an effluent abatement unit to remove toxic or hazardous components of the discharged gas, or the discharged gas may be recycled with appropriate verification or other treatment for reuse in the fabrication facility 400.

The gas environment in the interior volume 404 of the enclosure 402 may as mentioned be varied for the respective manufacturing operations carried out in the fabrication facility 400. The pyrolysis furnace and therefore have an internal ambient environment conducive to the pyrolysis operation. The pyrolysis furnace may be supplemented by a carbon pyrolyzate activation chamber in which the pyrolyzed adsorbent is activated at elevated temperature to prepare same for sorptive utilization of the gas desired to be stored on and subsequently desorbed from the adsorbent in dispensing operation of the gas supply package. The packaging of the pyrolyzed adsorbent articles in the gas storage and dispensing vessel may be carried out under another ambient gas environment, e.g., under hydrogen environment, to assist in reactively volatilizing any residual impurity species in the adsorbent articles, or otherwise effecting removal of impurity species or suppressing contamination of the adsorbent articles that would otherwise occur if the sorbent articles were exposed to ambient atmospheric conditions. Finally, the securement of the valve head assembly to the gas storage and dispensing vessel may be carried out under an atmosphere conducive to the securement operation.

The fabrication facility 400 thus includes a discharge locus at which pyrolyzed adsorbent articles from the pyrolysis operation (or from the pyrolysis/activation processing, if activation additionally is accommodated in the processing of the pyrolyzed adsorbent articles) are immediately introduced to the vessel of the gas supply package and the vessel is completed, so that the pyrolyzed adsorbent articles are maintained in a high-purity condition during such fabrication. The gas supply package is fabricated at the discharge locus, and the dispensing assembly can be welded or threadably engaged with the gas storage and dispensing vessel at such discharge locus. The pyrolyzed adsorbent articles may be introduced into the gas storage and dispensing vessel under an inert atmosphere (e.g., comprising one or more of nitrogen, helium, argon, xenon, and krypton) or in a reducing atmosphere of hydrogen, hydrogen sulfide, or other suitable gas, or a combination of inert gas and reducing gas.

In another aspect of the disclosure, high-purity carbon pyrolyzate articles may be packaged, as a pre-package, for subsequent installation in a gas supply package. For example, the carbon pyrolyzate articles once formed may be packaged at a discharge locus of the pyrolysis or pyrolysis/activation system, in a gas-impermeable bag or other pre-package container that is configured to be subsequently opened in situ after the packaged adsorbent has been installed in the gas supply package.

Such packaging approach for the carbon pyrolyzate adsorbent articles enables the articles to be maintained in a high-purity condition during storage, transport, etc., so that they may be introduced to the gas supply package without compromising the high-purity character of the adsorbent articles. The bag or other container in which the carbon pyrolyzate adsorbent articles are packaged may be formed of any suitable material that is sufficiently impermeable to deleterious gas species, to maintain the high-purity character of the adsorbent articles. Such gas impermeable material may for example comprise mylar or other metallized film, or multilayer polymeric film, or any other suitable material. The bags may be hermetically sealed.

The bagged or otherwise packaged adsorbent articles then may be installed in the vessel of the fluid supply package, with the vessel then being joined to a valve head assembly to complete the package, and with the bag or other packaging then being opened in situ in the vessel to expose the adsorbent articles so that they may sorptively take up gas thereafter charged to the vessel. Alternatively, the bag or other container of pre-packaged adsorbent articles may be introduced into the interior volume of the gas storage and dispensing vessel and the bag or container may be opened, prior to installation of the dispensing assembly on the vessel.

The opening or exposure of the adsorbent in situ in the gas supply package may be effected in any suitable manner. In one embodiment, the adsorbent articles are introduced into the vessel in a bag, which subsequent to securement of the valve head assembly is subjected to vacuum conditions, to cause the bag to burst, thereby exposing the adsorbent for use. In another embodiment, the bag may be caused to burst by the introduction of high pressure gas into the gas storage and dispensing vessel, whereby the resulting pressure differential on the bag causes it to burst open. Alternatively, the bag may be formed of material that is thermally degraded by heating of the vessel to rupture the bag and expose the adsorbent therein. As a further embodiment, the bag may be degraded by a specific gas to be held in the vessel, so that the gas reacts with the bag material to form a solid reaction product of negligible vapor pressure. The bag in a further embodiment may be provided with a closure that is activated by radio frequency to effect the in situ exposure of the adsorbent. It will be recognized that the exposure of the adsorbent in the bag may be carried out in any of a variety of other methods.

Once the adsorbent has been exposed, the gas to be stored on and subsequently desorbed and dispensed from the adsorbent, can be charged to the vessel, e.g., through a fill port of the valve head assembly.

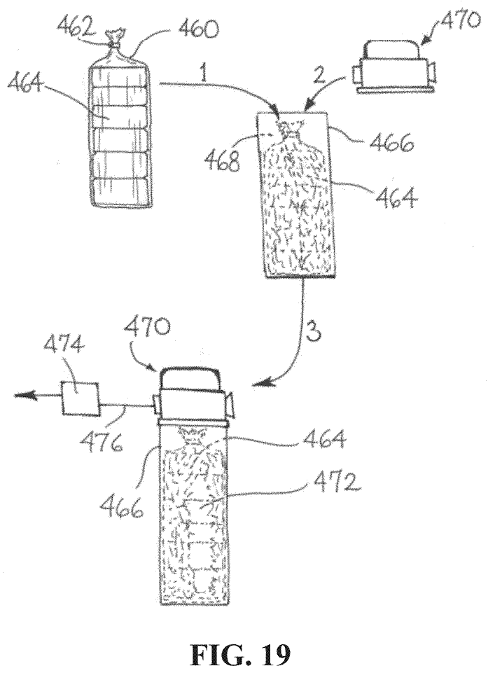

FIG. 19 is a schematic representation of a processing sequence for introducing high-purity carbon pyrolyzate adsorbent to a gas supply vessel that then is completed with a valve head assembly being installed, subsequent to which the adsorbent is exposed in situ.

As shown, a stack 464 of cylindrical disk-shaped carbon pyrolyzate adsorbent articles in a high-purity condition has been packaged in bag 460 which is secured at its upper end by closure 462. In such manner, the bagged adsorbent is prevented from contacting ambient gases.

In step 1 of the process sequence, indicated by the corresponding arrow in FIG. 5, the bagged adsorbent is introduced into the interior volume 468 of a gas storage and dispensing vessel 464, following which in step 2 a valve head assembly 470 is engaged with and secured to the vessel. The resulting gas supply package, with the valve head assembly 470 being secured to the gas storage and dispensing vessel 466 and containing the bagged adsorbent 464, then is coupled at the fill port of the valve head assembly to a vacuum pump 474, by means of fluid conduit 476. The vacuum pump 474 then exerts sufficient vacuum on the bag containing the adsorbent 464, to rupture same, producing an opening the 472 in the bag, and thereby exposing the adsorbent for subsequent adsorption of sortable gas.

Instead of exerting vacuum on the package to force the bursting of the package, when the adsorbent has for example been packaged at atmospheric pressure, the pump 474 may instead be joined to an external source of high pressure gas, which then is introduced under the action of the pump to the interior volume to exert pressure on the bag and correspondingly induce bursting of same to expose the adsorbent. It will be recognized that there are numerous ways in which the adsorbent can be packaged and exposed in situ for adsorption and storage of gas, and subsequent gas dispensing duty.

Thus, the disclosure contemplates a pre-package of carbon pyrolyzate articles, comprising a container holding an array of carbon pyrolyzate articles, the container being gas-impermeable and configured to be subsequently opened in situ after the prepackage of carbon pyrolyzate articles has been installed in a gas supply package.

The pre-package of carbon pyrolyzate articles may comprise a bag as the container, as described above, and the package may contain an array of carbon pyrolyzate articles in a stack of cylindrical disk-shaped carbon pyrolyzate articles, wherein adjacent pairs of carbon pyrolyzate articles in the stack are in phase-to-face abutting relationship to one another.

The disclosure further relates to a gas supply package comprising a gas storage and dispensing vessel holding a pre-package of carbon pyrolyzate articles as described above, and a gas dispensing assembly secured to the gas storage and dispensing vessel.

In a further aspect, the disclosure relates to a method of supplying gas for use, comprising providing for installation in a gas supply package a pre-package of carbon pyrolyzate articles as described above. A further aspect of the disclosure relates to a method of supplying a gas for use, comprising installing in a gas supply package a pre-package of carbon pyrolyzate articles as described above. Yet another aspect of the disclosure relates to a method of supplying a gas for use, comprising opening a pre-package of carbon pyrolyzate articles as described above, in situ in a gas supply package.

In a further aspect, the disclosure relates to a method of enhancing purity of a carbon pyrolyzate adsorbent, comprising contacting the adsorbent with a displacing gas that is effective to displace impurities from the adsorbent, and removing the displacing gas from the adsorbent, to yield an enhanced purity carbon pyrolyzate adsorbent.

Such process thus provides a pickling technique to enhance purity of the adsorbent. The pickling method may be carried out at elevated temperature, with modulation of temperature, for extended periods of time, e.g., a period of time sufficient to remove at least 98% by weight of the impurities from the adsorbent, and/or with modulation of pressure, and in a cyclic repetitive manner involving a number of pump/purge steps in which the displacing gas is flowed to the adsorbent for contacting therewith, followed by purging of the displacing gas from the adsorbent, and the contacting/purging steps are carried out for at least one repeated cycle.

In specific applications, the displacing gas could be employed as a surrogate compound that is effective to achieve the desired displacement of adsorbed impurities from the adsorbent. The displacing gas may be a reducing gas such as hydrogen, hydrogen sulfide, or other suitable gas, rather than the intended sorbate gas, to effect displacement of impurities and enhance purity of the adsorbent prior to charging of the intended sorbate gas for sorptive storage on the adsorbent, and subsequent dispensing use when the gas is desorbed from the adsorbent under dispensing conditions. Such use of reducing gas such as hydrogen or hydrogen sulfide is particularly cost-effective when the intended sorbate gas is an expensive gas such as germanium tetrafluoride (GeF₄). In other embodiments, the displacing gas may comprise an inert gas, e.g., nitrogen, helium, argon, nitrogen, krypton, or combinations of two or more of such gases. In still other embodiments, the displacing gas may comprise an inert gas in combination with a reducing gas.

The above-described enhancement of purity may be carried out with elevated temperature degassing of the adsorbent, and optionally with use of elevated pressure displacing gas, e.g., at pressure of 20 to 1600 psig, or at other suitable superatmospheric pressure, to initially maximize the removal of impurity, followed by the degassing to remove the displacing gas from the adsorbent.

The purity of the gas supplied by the gas supply package may be enhanced by use of a filter at the discharge port of the valve head assembly of the gas supply package. The filter may comprise a replaceable filter element, or an element that is able to be processed for removal of contaminant, to accommodate reuse of the filter element.

The purity of the gas supply to the gas supply package may additionally, or alternatively, be enhanced by deployment in the interior volume of the gas storage and dispensing vessel of a desiccant or scrubber medium, e.g., a CO₂ getter, which is effective to remove impurities species of interest.

Although the disclosure herein is primarily directed to carbon pyrolyzate adsorbents, alternative adsorbents may be employed in any of the applications described herein, to the extent that alternative adsorbents may be useful and are advantageous. In one aspect, the disclosure contemplates an alternative adsorbent, comprising molybdenum disulfide (MoS₂), which may be provided with any form factor, including the shapes and conformations variously described herein in the use of carbon pyrolyzate adsorbents (e.g., powder, granules, pellets, monolithic forms, etc.). In a specific embodiment, the adsorbent comprises a multiplicity of adsorbent articles of monolithic form.

Accordingly, the disclosure in a further aspect relates to a gas supply package comprising adsorbent for holding adsorbed gas for storage thereon and desorbing gas for discharge from the gas supply package under dispensing conditions of the package, wherein the adsorbent comprises molybdenum disulfide (MoS₂).

Enhanced purity by removal of impurities species on the adsorbent material may further be enhanced by use of adsorbent article forms that provide appropriate levels of interstitial space between the adsorbent articles to provide interstitial void volume enabling more efficient degassing of the adsorbent to be carried out, as well as adsorbent material articles, e.g., tablets or pellets or other suitable forms, that are made smaller to provide more void space for more efficient degassing for impurity removal.

In one aspect, the disclosure relates to a method of enhancing purity of a carbon pyrolyzate adsorbent, comprising providing the adsorbent in a divided form and divided form size to achieve removal of at least 98% by weight of impurities in the carbon pyrolyzate adsorbent when the adsorbent is subjected to degassing, and degassing the adsorbent to achieve such removal.

An additional impurity-decreasing approach relates to the material of construction of the gas storage and dispensing vessel, which may contain impurities species or accommodate diffusional ingress of impurities species, which then subsequently may out-gas in the subsequent transport, storage, installation, and use of the gas supply package. The gas storage and dispensing vessel may for example be formed of aluminum or other material that is readily passivated to minimize undesirable impurity egress from the vessel wall and floor surfaces, or the gas storage and dispensing vessel may be plated, coated, or otherwise provided with a film or layer of such lower-impurity material on a vessel over its interior surfaces, and optionally over exterior surfaces of the vessel.

Accordingly, the disclosure relates in another aspect to a gas supply package comprising a gas storage and dispensing vessel holding an adsorbent gas storage medium, and a gas dispensing assembly secured to the vessel, wherein the vessel comprises a material of construction having a relatively higher content of impurity susceptible to egress in an interior volume of the vessel and presenting an interior surface in the interior volume of the vessel, wherein the interior surface is plated with a material having a relatively lower content of impurity susceptible to egress in the interior volume of the vessel.

In another aspect, the disclosure relates to a gas supply package comprising a gas storage and dispensing vessel holding an adsorbent gas storage medium, and a gas dispensing assembly secured to the vessel, wherein the vessel comprises aluminum or aluminum alloy as a material of construction.

In addition to plating or overlaying vessel surfaces with purity-enhancing materials, the vessel may be processed to provide a polished or smoother interior surface finish, e.g., a mirror finish on interior surfaces of the vessel.

The disclosure therefore contemplates in another aspect a method of enhancing purity of gas dispensed from a gas supply package comprising a gas storage and dispensing vessel holding an adsorbent gas storage medium, and a gas dispensing assembly secured to the vessel, such method comprising fabricating the vessel of the gas supply package to comprise interior vessel surface having a polished, smooth interior surface finish.

Additional techniques to enhance purity of gas dispensed from the gas supply package in the use of the package, include quick-pumping of the headspace in the interior volume of the gas storage and dispensing vessel, to remove impurities that may have concentrated in the headspace. The headspace is the portion of the interior volume of the vessel overlying the adsorbent, and the impurities as a result of displacement by the sorbate gas, or vapor pressure effects in the sealed gas vessel before or after charging of the sorbate gas, may accumulate in the headspace, so that a rapid, transient pumping of the headspace through a port of the valve head assembly (e.g., either the fill port or the discharge port thereof) is effective to remove the headspace impurities.

The disclosure therefore contemplates in a further aspect a method of enhancing purity of gas dispensed from a gas supply package in use, the gas supply package comprising a gas storage and dispensing vessel holding an adsorbent gas storage medium, and a gas dispensing assembly secured to the vessel, where the vessel comprises interior volume including a headspace above the adsorbent gas storage medium, the method comprising quick-pumping the headspace, before or after charging the package with sorbate gas.

In connection with the foregoing approaches to enhance purity, which may be used in any combinations and permutations of the various individual techniques, the gas supply package may be provided for use with a complement of post-fill analysis data, directed to the characteristics of the gas in the vessel, including its purity level. Such data may be provided in an RFID tag or other data storage device on the vessel, or in a printed label form on the vessel, or as a separate printed report, so that the vessel when sold, transported, stored, and/or installed, may readily be verified as meeting specific gas purity criteria, in addition to identification of other characteristics of the supplied gas and/or the gas supply package in which the gas is provided.

The disclosure therefore contemplates in a further aspect a gas supply package kit, comprising (i) a gas supply package comprising a gas storage and dispensing vessel holding an adsorbent gas storage medium having sorbate gas adsorbed thereon, and a gas dispensing assembly secured to the vessel for discharging the sorbate gas from the package under dispensing conditions thereof, and (ii) post-fill analysis data for the supplied gas including gas purity, in a data presentation article or device.

The disclosure relates in a further aspect to a gas supply package comprising a gas storage and dispensing vessel holding an adsorbent gas storage medium for storage of sorbate gas thereon, and a gas dispensing assembly secured to the vessel for discharging the sorbate gas from the package under dispensing conditions thereof, wherein the vessel comprises a DOT3AA cylinder, and the adsorbent gas storage medium comprises a PVDC-based polymer or copolymer pyrolyzate adsorbent, e.g., a PVDC-MA carbon pyrolyzate adsorbent. The adsorbent may be in any suitable form, e.g., in a pellet and/or bead form.

The pellets and/or beads of the adsorbent may suitably be of differing carbon pyrolyzate type or types, having varied adsorbent characteristics, such as pore size, pore size distribution, bulk density, ash content, permeability, etc., so as to provide a blend of adsorbent articles suited for a specific sorbate gas to be delivered by the gas supply package in use.

In a further aspect, the disclosure relates to a carbon pyrolyzate adsorbent provided in the form of rods, as elongate adsorbent articles that may for example have a length (L) to diameter (D) ratio in a range of from 20 to 90, or of other L/D characteristics. As used in such context, the term diameter refers to a maximal transverse dimension, perpendicular to the axial or length direction of the adsorbent article. The rod may have any suitable cross-sectional shape, e.g., square, rectangular, circular, ovoid, cruciform, etc. The adsorbent rods may readily be formed with a circular cross-section from a pyrolyzable starting material that is extruded through a circular cross-section extrusion die, with the extrudate being severed at desired lengths to provide the starting material that by pyrolysis and subsequent optional activation yield the carbon pyrolyzate adsorbent in rod form.

Rods of the carbon pyrolyzate adsorbent may for example be formed, and a multiplicity of such rods may be bundled to constitute rod assemblies, which may for example be banded or otherwise consolidated with one another in a unitary assembly. The bundle may therefore comprise an assembly of rod articles in which each of the rods is parallelly oriented with others in the bundle. A bundle of such rods may for example be placed in a neck opening of a gas storage and dispensing vessel, to “tune” the dispensing of the gas from the vessel under dispensing conditions. In such instance, the rod bundle of adsorbent rod articles can be retained in position in the neck or otherwise in the interior volume of a gas storage and dispensing vessel by positioning devices, such as a compression wedge sure spring to ensure the maintenance of a specific position of the rod bundle in the interior volume.

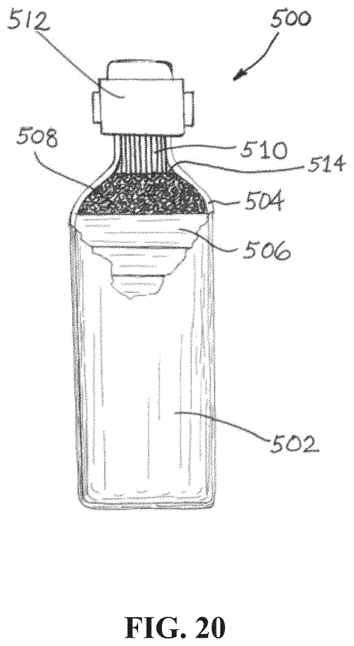

FIG. 20 is a schematic representation of a gas supply package according to a further aspect of the disclosure, comprising adsorbent in a multiplicity of forms, including rods that are bundled in the neck of the gas storage and dispensing vessel of such package.

As illustrated, the gas supply package 500 includes a gas storage and dispensing vessel 502 defining an interior volume therewithin, enclosed by the vessel wall 504. In the interior volume of the vessel, a multiplicity of forms of carbon pyrolyzate adsorbent are provided, including a stack of disk-shaped adsorbent articles 506 in which adjacent pairs of discs are in face-to-face abutting relationship with one another. On the uppermost disk in the stack is provided a mixed population 508 of rods and beads of adsorbent. The mixed population of rods and beads of adsorbent may be retained in position by a screen 514 or other foraminous retention element in the interior volume, if desired. Overlying the mixed population of rods and beads of adsorbent is a bundle 510 of adsorbent rods that are inserted in the neck of the vessel 502. The rods may be reposed at their lower extremities on the screen 514, or otherwise be retained in position in the neck of the vessel.

The vessel at its upper end is secured to dispensing head assembly 512, containing fill and discharge ports for charging of gas to the vessel, and for dispensing gas from the package under dispensing conditions of the package. The dispensing head assembly 512 may include a valve actuator or other structure for translating a valve in the dispensing head assembly between fully open and fully closed positions.

The gas supply package illustrated in FIG. 20 it therefore illustrates a gas supply package of the present disclosure in which a multiplicity of forms of carbon pyrolyzate adsorbent are employed. The rods as arranged in a bundle therefore include interstitial space between adjacent rods, through which gas can pass in egress from the vessel to the dispensing head assembly for subsequent discharge at the discharge port of such dispensing head assembly. The rods therefore may be provided to modulate gas release from the vessel, so that initial opening of a previously closed valve in the dispensing head assembly does not result in propagation of pressure spikes or other perturbations of the flow of the dispensed gas.

A gas supply package may be utilized in accordance with the present disclosure, as comprising a variety of adsorbent types and forms in the package. For example, a specific form of the adsorbent having relatively slower gas transfer characteristics may be provided together with a higher permeability adsorbent providing higher fill and gas delivery rates, to provide a desired flow of dispensed gas from the package.

In one aspect, the disclosure relates to a gas supply package comprising a gas storage and dispensing vessel holding an adsorbent gas storage medium for storage of sorbate gas thereon, and a gas dispensing assembly secured to the vessel for discharging the sorbate gas from the package under dispensing conditions thereof, wherein the adsorbent medium comprises a bundle of carbon pyrolyzate adsorbent articles as described above, wherein the bundle is positioned in a neck portion of the vessel.

Such gas supply package may further comprise adsorbent medium in other, non-rod forms, such as monolithic forms (e.g., cylindrical disc articles), bead forms, and/or pellet forms, in any suitable combinations and permutations.

The disclosure in a further aspect relates to approaches for increasing deliverable capacity of a gas supply package that comprises a gas storage and dispensing vessel holding an adsorbent gas storage medium for storage of sorbate gas thereon, and a gas dispensing assembly secured to the vessel for discharging the sorbate gas from the package under dispensing conditions thereof.

One such approach, as employed in various embodiments of the gas supply package, is to utilize adsorbent therein that is processed by pyrolysis of a pyrolyzable starting material and subsequent activation and degassing, wherein the processing is dependent on the sorbate gas to be stored on and subsequently dispensed from the adsorbent, and is applied to achieve increase in capacity of the carbon pyrolyzate adsorbent. Process variables of the processing that are selected to achieve a predetermined activation of the carbon pyrolyzate adsorbent include activation temperature and activation time. The pyrolysis operation may be likewise selected for the goal of enhancing the capacity of the carbon pyrolyzate adsorbent for the sorbate gas, with respect to pyrolysis time and temperature. The degassing operation in which extraneous species are removed from the carbon pyrolyzate adsorbent may be correspondingly subject to selection of specific degas temperature, final (at the end of the degassing operation) pressure, and degassing time, to achieve a specific level of capacity enhancement of the carbon pyrolyzate adsorbent.

Accordingly, the disclosure contemplates a method of manufacturing gas supply packages including packages used to supply different gases, wherein the gas supply packages each comprise a gas storage and dispensing vessel holding an adsorbent for storage of sorbate gas thereon, and a gas dispensing assembly secured to the vessel for discharging the sorbate gas from the package under dispensing conditions thereof, said method comprising preparing adsorbents by processing including pyrolysis of a pyrolyzable starting material and subsequent activation and degassing, followed by packaging of the adsorbents in the gas supply packages, wherein the processing is carried out according to processing conditions that are specific for the sorbate gas to be employed in a gas supply package comprising such adsorbent, and wherein the processing conditions differ for the adsorbents that are packaged in different gas supply packages for supply of different gases.

In such method, the differing processing conditions may differ in at least one condition selected from the group consisting of activation temperature, activation time, pyrolysis time, pyrolysis temperature, degas temperature, final degas pressure, and degassing time.

Another approach for enhancing the deliverable capacity of the gas supply package focuses on reducing the heel, i.e., the residual gas in the gas supply package that remains at the conclusion of the dispensing operation. The heels content of exhausted gas supply packages represent a waste of the gas, which in various applications of manufacture of products such as semiconductor products, flat-panel displays, and solar panels, may represent a significant cost of the process, since the heels content of the package may simply be left in the vessel at the conclusion of use, and may subsequently be vented or otherwise disposed of in a manner that fails to achieve utilization of the gas, which may be of an expensive character.

In the effort to minimize heel in the exhausted gas supply package, it may be advantageous to utilize different types or forms of the carbon pyrolyzate adsorbent in the package, by which the heels gas is more readily desorbed for dispensing, so that more of the gas inventory of the package is actually discharged for use.

Thus, the disclosure contemplates a method of reducing heels content at exhaustion of a gas supply package comprising a gas storage and dispensing vessel holding adsorbent for storage of sorbate gas thereon, and a gas dispensing assembly secured to the vessel for discharging the sorbate gas from the package under dispensing conditions thereof, such method comprising providing, as the adsorbent, adsorbent species of at least one of differing type and differing form, wherein the different type(s) and/or form(s) increase the amount of sorbate gas desorbed from the adsorbent under said dispensing conditions, in relation to adsorbent of a single one of said adsorbent species.

As another approach for minimizing heel content of the gas supply package, in instances in which the sorbate gas comprises an isotopically enriched gas, i.e., a gas that is enriched in one or more isotopes at a level above natural abundance of the isotope(s), and wherein the isotopically enriched gas is substantially more costly than the corresponding natural abundance gas, containing a naturally occurring complement of the respective isotopes of the gaseous compound. In such instances, it may be advantageous to utilize a corresponding natural abundance gas to fill the gas supply package to a low initial pressure to establish the heel, with the corresponding isotopically enriched gas then being utilized as the principal charging gas for loading the carbon pyrolyzate adsorbent in the gas supply package with the desired sorbate gas, so that the isotopically enriched gas is used to fill the “pre-heeled” adsorbent to a desired fill pressure or other measure of fill capacity.

In this manner, the isotopically enriched gas can be dispensed during normal dispensing operation while the natural abundance gas is retained as the heels portion of the gas in the vessel, so that no significant economic penalty is paid by reason of the non-dispensable character of the heels gas.

Accordingly, the disclosure contemplates a method of reducing heels content at exhaustion of a gas supply package comprising a gas storage and dispensing vessel holding adsorbent for storage of isotopically-enriched sorbate gas thereon, and a gas dispensing assembly secured to the vessel for discharging the sorbate gas from the package under dispensing conditions thereof, said method comprising initially charging the adsorbent in the gas storage and dispensing vessel of the gas supply package with corresponding non-isotopically-enriched sorbate gas in an amount sufficient to establish a gas heel, and after establishment of the gas heel, charging the adsorbent in the gas storage and dispensing vessel with the isotopically-enriched sorbate gas to a predetermined fill capacity of the gas supply package.

The sorbate gas in such method may comprise any suitable gas, e.g., a gas selected from the group consisting of boron trifluoride, silane, silicon tetrafluoride, germanium tetrafluoride, and germane.

The disclosure also relates in a corresponding aspect to a gas supply package comprising a gas storage and dispensing vessel holding adsorbent for storage of sorbate gas thereon, and a gas dispensing assembly secured to the vessel for discharging the sorbate gas from the package under dispensing conditions thereof, wherein the sorbate gas inventory in the gas storage and dispensing vessel comprises a heel portion comprising non-isotopically-enriched sorbate gas, and a remaining non-heel portion comprising corresponding isotopically-enriched sorbate gas.

In various embodiments, the adsorbent in such gas supply package may comprise a carbon pyrolyzate adsorbent of suitable type, and more generally may comprise any adsorbent disclosed herein.

The sorbate gas likewise may be of any suitable type, and may for example comprise gas selected from the group consisting of boron trifluoride, silane, silicon tetrafluoride, germanium tetrafluoride, and germane.

While the disclosure has been set forth herein in reference to specific aspects, features and illustrative embodiments, it will be appreciated that the utility of the disclosure is not thus limited, but rather extends to and encompasses numerous other variations, modifications and alternative embodiments, as will suggest themselves to those of ordinary skill in the field of the present disclosure, based on the description herein. Correspondingly, the disclosure as hereinafter claimed is intended to be broadly construed and interpreted, as including all such variations, modifications and alternative embodiments, within its spirit and scope.

What is claimed is:

1. A process for fabricating a gas supply package, comprising:
supplying a pyrolyzable precursor material to a pyrolysis furnace to produce a carbon pyrolyzate adsorbent; and
discharging the carbon pyrolyzate adsorbent from the pyrolysis furnace to an interior volume of a gas storage and dispensing vessel.

2. The process of claim 1, wherein the carbon pyrolyzate adsorbent is discharged directly from the pyrolysis furnace to the gas storage and dispensing vessel.

3. The process of claim 1, wherein at least one of the pyrolysis furnace, the gas storage and dispensing vessel, or any combination thereof is at least partially located within a single enclosure configured to maintain purity of the gas supply package.

4. The process of claim 1, further comprising:
activating the carbon pyrolyzate adsorbent in an activation chamber.

5. The process of claim 4, wherein at least one of the pyrolysis furnace, the gas storage and dispensing vessel, the activation chamber, or any combination thereof is at least partially located within a single enclosure configured to maintain purity of the gas supply package.

6. The process of claim 1, further comprising:
securing a valve head dispensing assembly to the gas storage and dispensing vessel at an assembly station.

7. The process of claim 6, wherein at least one of the pyrolysis furnace, the gas storage and dispensing vessel, the assembly station, or any combination thereof is at least partially located within a single enclosure configured to maintain purity of the gas supply package.

8. The process of claim 1, wherein a form of the pyrolyzable precursor material comprises at least one of powder, granules, pellets, monolithic forms, bricks, blocks, boules, cylindrical discs, or any combination thereof.

9. A method comprising:
obtaining a carbon pyrolyzate adsorbent,
wherein the carbon pyrolyzate adsorbent comprises adsorbed impurities;
contacting the carbon pyrolyzate adsorbent with a displacing gas sufficient to displace the adsorbed impurities from the carbon pyrolyzate adsorbent,
wherein, following the contacting, the carbon pyrolyzate adsorbent comprises at least a portion of the displacing gas; and
degassing the carbon pyrolyzate adsorbent sufficient to remove at least one of the displacing gas, displaced impurities, or any combination thereof from the carbon pyrolyzate adsorbent.

10. The method of claim 9, wherein a duration of the contacting is sufficient to result in removal of at least 98% by weight of the adsorbed impurities based on a total weight of the adsorbed impurities.

11. The method of claim 9, further comprising adjusting a temperature of at least one of the contacting, the degassing, or any combination thereof sufficient to result in removal of at least 98% by weight of the adsorbed impurities based on a total weight of the adsorbed impurities.

12. The method of claim 9, further comprising adjusting a pressure of at least one of the contacting, the degassing, or any combination thereof sufficient to result in removal of at least 98% by weight of the adsorbed impurities based on a total weight of the adsorbed impurities.

13. The method of claim 9, wherein the degassing comprises purging the displacing gas from the carbon pyrolyzate adsorbent.

14. The method of claim 9, wherein the displacing gas comprises at least one of a reducing gas, an inert gas, or any combination thereof.

15. The method of claim 14, wherein the reducing gas comprises at least one of hydrogen, hydrogen sulfide, or any combination thereof.

16. The method of claim 14, wherein the inert gas comprises at least one of nitrogen, helium, argon, xenon, krypton, or any combination thereof.

17. A gas supply package, comprising:
a vessel comprising:
a vessel wall having an interior surface that defines an interior volume,
wherein the interior surface of the vessel wall comprises a first material; and
a material layer covering at least a portion of the interior surface of the vessel wall,
wherein the material layer comprises a second material that is different from the first material;
wherein the first material has a greater content of impurity susceptible to egress into the interior volume of the vessel than the second material; and
an adsorbent gas storage medium disposed within the interior volume of the vessel.

18. The gas supply package of claim 17, wherein the material layer forms a coating covering at least a portion of the interior surface of the vessel wall.

19. The gas supply package of claim 17, wherein the material layer forms a plated surface covering at least a portion of the interior surface of the vessel wall.

20. The gas supply package of claim 17, wherein the first material further has a greater content of reactive species susceptible to reaction with an adsorbate gas species than the second material.
